(19) United States
(12) Patent Application Publication
(10) Pub. No.: US 2025/0374694 A1
(43) Pub. Date: Dec. 4, 2025

(54) PHOTODETECTION DEVICE

(71) Applicant: SONY SEMICONDUCTOR SOLUTIONS CORPORATION, KANAGAWA (JP)

(72) Inventors: YU SHIIHARA, KANAGAWA (JP); HIDEO KIDO, KANAGAWA (JP); TAKASHI MACHIDA, KANAGAWA (JP)

(21) Appl. No.: 18/730,037

(22) PCT Filed: Jan. 12, 2023
(86) PCT No.: PCT/JP2023/000519

§ 371 Date: Mar. 3, 2025

(30) Foreign Application Priority Data
Jan. 26, 2022 (JP) 2022-010132

(51) Int. Cl. H10F 39/00; H10F 39/12; H10F 39/18

(52) U.S. Cl. CPC H10F 39/8057; H10F 39/182; H10F 39/811; H10F 39/014; H10F 39/199

(57) ABSTRACT

The present disclosure relates to a photodetection device capable of achieving both a shielding effect and heat resistance on a second-layer pixel substrate and suppressing parasitic light reception sensitivity on the second-layer pixel substrate.

A photodetection device includes: a first substrate including a first semiconductor substrate on which at least a photoelectric conversion unit is formed; a second substrate including a second semiconductor substrate on which an active element is formed; and a dielectric multilayer film configured by alternately stacking at least three or more layers of a first film using a dielectric material having a first refractive index and a second film using a dielectric material having a second refractive index lower than the first refractive index, the dielectric multilayer film being disposed between the first semiconductor substrate and the second semiconductor substrate. The present disclosure can be applied to, for example, a solid-state imaging device or the like including a pixel that receives incident light and performs photoelectric conversion.

### TECHNICAL FIELD

The present disclosure relates to a photodetection device, and particularly to a photodetection device capable of achieving both a shielding effect and heat resistance on a second-layer pixel substrate, and suppressing parasitic light reception sensitivity on the second-layer pixel substrate.

### BACKGROUND ART

Patent Document 1 reports a structure for suppressing propagation of electromagnetic waves and heat between elements formed on upper and lower substrates and suppressing deterioration of characteristics of the elements in a CMOS image sensor in which a plurality of substrates is stacked.

Among the structures described in Patent Document 1, according to a structure including a shield layer containing a conductive material between element layers, it is disclosed that parasitic light reception sensitivity (PLS) can be suppressed in a substrate (Hereinafter, it is referred to as a second-layer pixel substrate.) not including a photoelectric conversion unit, and propagation of other electromagnetic noises can be suppressed. Furthermore, it is disclosed that, according to a structure in which a structure having a minute size and a high refractive index is provided in an insulating layer, light is totally reflected at an interface between the structure and the insulating layer, so that an optical path length is extended and the light is attenuated, whereby parasitic light reception sensitivity can be suppressed. Furthermore, according to a structure using a dielectric film having a refractive index intermediate between a refractive index of the insulating layer and a refractive index of the silicon substrate as an antireflection part, it is disclosed that color mixing noise due to reflection on the silicon substrate can be suppressed.

### CITATION LIST

### Patent Document

Patent Document 1: WO 2020/262583 A

### SUMMARY OF THE INVENTION

### Problems to be Solved by the Invention

However, in the structure in which metal is used as a conductive material for the shield layer, heat treatment for element formation or activation cannot be performed after formation of the shield layer due to a melting point problem. Therefore, it is necessary to perform bonding after the element formation, but in this case, the lead time becomes long and the wiring layer increases. Furthermore, in a structure in which a nonmetallic conductive material or a ferromagnetic material having heat resistance is used for the shield layer, both the reflectance and the absorption rate are insufficient, and the shielding effect is lowered. In the configuration in which the optical path length is extended with a structure having a minute size and a high refractive index, the effect of suppressing PLS is insufficient, and in the structure in which the antireflection part is provided, electromagnetic shielding to the second-layer pixel substrate cannot be performed.

As described above, there is room for improvement in the shield layer that achieves both the sufficient shielding effect and the heat resistance on the second-layer pixel substrate.

The present disclosure has been made in view of such a situation, and an object of the present disclosure is capable of achieving both a shielding effect and heat resistance on a second-layer pixel substrate, and suppressing parasitic light reception sensitivity in the second-layer pixel substrate.

### Solutions to Problems

A photodetection device according to a first aspect of the present disclosure includes:
a first substrate including a first semiconductor substrate on which at least a photoelectric conversion unit is formed;
a second substrate including a second semiconductor substrate on which an active element is formed; and
a dielectric multilayer film configured by alternately stacking at least three or more layers of a first film using a dielectric material having a first refractive index and a second film using a dielectric material having a second refractive index lower than the first refractive index, the dielectric multilayer film being disposed between the first semiconductor substrate and the second semiconductor substrate.

In the first aspect of the present disclosure, there is provided: a first substrate including a first semiconductor substrate on which at least a photoelectric conversion unit is formed; a second substrate including a second semiconductor substrate on which an active element is formed; and a dielectric multilayer film configured by alternately stacking at least three or more layers of a first film using a dielectric material having a first refractive index and a second film using a dielectric material having a second refractive index lower than the first refractive index, the dielectric multilayer film being disposed between the first semiconductor substrate and the second semiconductor substrate.

A photodetection device according to a second aspect of the present disclosure includes:
a first substrate including a first semiconductor substrate on which at least a photoelectric conversion unit is formed; and
a second substrate including a second semiconductor substrate on which an active element is formed,
in which the first substrate and the second substrate are stacked, and
the second substrate includes a light shielding film on the second semiconductor substrate.

In the second aspect of the present disclosure, a first substrate including a first semiconductor substrate on which at least a photoelectric conversion unit is formed, and a second substrate including a second semiconductor substrate on which an active element is formed are stacked, and a light shielding film is provided on the second semiconductor substrate of the second substrate.

The photodetection device may be an independent device or a module incorporated into another device.

### BRIEF DESCRIPTION OF DRAWINGS

FIG. 1 is a diagram illustrating a schematic configuration of a solid-state imaging device to which the technology of the present disclosure is applied.

FIG. 2 is a diagram illustrating a circuit configuration example of a pixel.

FIG. 3 is a cross-sectional view schematically illustrating a first structure example of a pixel in the first embodiment.

FIG. 4 is a diagram for explaining a simulation result of a dielectric multilayer film.

FIG. 5 is a diagram for explaining a method of manufacturing the pixel of the first structure example of FIG. 4.

FIG. 6 is a diagram for explaining the method of manufacturing the pixel of the first structure example of FIG. 4.

FIG. 7 is a cross-sectional view schematically illustrating a second structure example of the pixel in the first embodiment.

FIG. 8 is a diagram for explaining a method of manufacturing a pixel of the second structure example of FIG. 7.

FIG. 9 is a cross-sectional view schematically illustrating a third structure example of the pixel in the first embodiment.

FIG. 10 is a diagram for explaining a method of manufacturing the pixel of the third structure example of FIG. 9.

FIG. 11 is a cross-sectional view schematically illustrating a fourth structure example of the pixel in the first embodiment.

FIG. 12 is a cross-sectional view schematically illustrating a fifth structure example of the pixel in the first embodiment.

FIG. 13 is a cross-sectional view schematically illustrating a sixth structure example of the pixel in the first embodiment.

FIG. 14 is a cross-sectional view schematically illustrating a seventh structure example of the pixel in the first embodiment.

FIG. 15 is a cross-sectional view schematically illustrating an eighth structure example of the pixel in the first embodiment.

FIG. 16 is a cross-sectional view schematically illustrating a ninth structure example of the pixel in the first embodiment.

FIG. 17 is a diagram illustrating a method of manufacturing the pixel in the eighth structure example in FIG. 15 and the ninth structure example in FIG. 16.

FIG. 18 is a diagram schematically illustrating a first structure example of a pixel according to a second embodiment.

FIG. 19 is a diagram for explaining a method of manufacturing the pixel of the first structure example in FIG. 18.

FIG. 20 is a diagram for explaining the method of manufacturing the pixel of the first structure example in FIG. 18.

FIG. 21 is a diagram for explaining the method of manufacturing the pixel of the first structure example in FIG. 18.

FIG. 22 is a diagram for explaining the method of manufacturing the pixel of the first structure example in FIG. 18.

FIG. 23 is a cross-sectional view schematically illustrating a second structure example of the pixel in the second embodiment.

FIG. 24 is a cross-sectional view schematically illustrating a third structure example of the pixel in the second embodiment.

FIG. 25 is a diagram for explaining a method of manufacturing the pixel of the third structure example of FIG. 24.

FIG. 26 is a diagram for explaining the method of manufacturing the pixel of the third structure example of FIG. 24.

FIG. 27 is a diagram for explaining the method of manufacturing the pixel of the third structure example of FIG. 24.

FIG. 28 is a diagram for explaining the method of manufacturing the pixel of the third structure example of FIG. 24.

FIG. 29 is a cross-sectional view schematically illustrating a fourth structure example of the pixel in the second embodiment.

FIG. 30 is a cross-sectional view schematically illustrating a fifth structure example of the pixel in the second embodiment.

FIG. 31 is an enlarged cross-sectional view of the vicinity of a gate electrode of an amplification transistor in the fifth structure example.

FIG. 32 is a diagram illustrating another circuit configuration example of the pixel.

FIG. 33 is a diagram illustrating a schematic configuration example of a solid-state imaging device in a case where three substrates are stacked.

FIG. 34 is a diagram illustrating a usage example of an image sensor.

FIG. 35 is a block diagram illustrating a configuration example of an imaging device as an electronic device to which the technology of the present disclosure is applied.

FIG. 36 is a block diagram illustrating an example of a schematic configuration of a vehicle control system.

FIG. 37 is an explanatory diagram illustrating an example of installation positions of an outside-vehicle information detecting unit and an imaging section.

### MODE FOR CARRYING OUT THE INVENTION

Hereinafter, modes for carrying out the technique of the present disclosure (hereinafter, it is referred to as embodiments) will be described with reference to the accompanying drawings. The description is given in the following order.
1. Schematic configuration example of solid-state imaging device
2. Configuration example of pixel circuit
3. First embodiment of pixel
   3.1 First structure example of pixel according to first embodiment
   3.2 Method of manufacturing first structure example of pixel
   3.3 Second structure example of pixel according to first embodiment
   3.4 Method of manufacturing second structure example of pixel
   3.5 Third structure example of pixel according to first embodiment
   3.6 Method of manufacturing third structure example of pixel
   3.7 Fourth structure example of pixel according to first embodiment
   3.8 Fifth structure example of pixel according to first embodiment
   3.9 Sixth structure example of pixel according to first embodiment
   3.10 Seventh structure example of pixel according to first embodiment
   3.11 Eighth structure example of pixel according to first embodiment
   3.12 Ninth structure example of pixel according to first embodiment
   3.13 Manufacturing method of eighth structure example and ninth structure example of pixel
4. Summary of pixels according to first embodiment
5. Second embodiment of pixel
   5.1 First structure example of pixel according to second embodiment
   5.2 Method of manufacturing first structure example of pixel
   5.3 Second structure example of pixel according to second embodiment
   5.4 Third structure example of pixel according to second embodiment
   5.5 Method of manufacturing third structure example of pixel
   5.6 Fourth structure example of pixel according to second embodiment
   5.7 Fifth structure example of pixel according to second embodiment
6. Summary of pixels according to second embodiment
7. Another configuration example of pixel circuit
8. Configuration example of three layer substrate
9. Usage example of image sensor
10. Application example to electronic device
11. Application to general photodetection devices
12. Application example to mobile body

Note that, in the drawings referred to in the following description, the same or similar parts are denoted by the same or similar reference signs, and redundant description will be omitted as appropriate. The drawings are schematic, and the relationship between the thickness and the plane dimension, the ratio of the thickness of each layer, and the like are different from the actual ones. Furthermore, the drawings may include portions having different dimensional relationships and ratios.

Furthermore, the definitions of directions such as up and down or the like in the following description are merely definitions for convenience of description, and do not limit the technical idea of the present disclosure. For example, when an object is observed by rotating the object by 90°, the up and down are converted into and read as left and right, and when the object is observed by rotating the object by 180°, the up and down are inverted and read.

### 1. Schematic Configuration Example of Solid-State Imaging Device

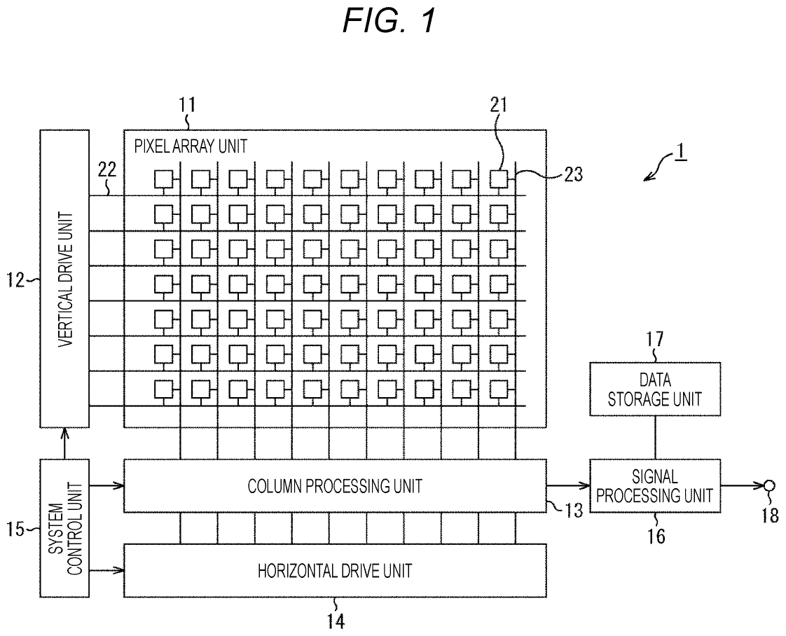

FIG. 1 is a diagram illustrating a schematic configuration of a solid-state imaging device to which the technology of the present disclosure is applied.

The solid-state imaging device 1 in FIG. 1 illustrates a configuration of a CMOS image sensor which is a type of solid-state imaging device of an X-Y address system, for example. The CMOS image sensor is an image sensor manufactured by applying or partially using a CMOS process.

The solid-state imaging device 1 includes a pixel array unit 11 and a peripheral circuit unit. The peripheral circuit unit includes, for example, a vertical drive unit 12, a column processing unit 13, a horizontal drive unit 14, and a system control unit 15.

The solid-state imaging device 1 further includes a signal processing unit 16 and a data storage unit 17. The signal processing unit 16 and the data storage unit 17 may be mounted on the same substrate as the pixel array unit 11, the vertical drive unit 12, and the like, or may be disposed on another substrate. Furthermore, each processing of the signal processing unit 16 and the data storage unit 17 may be executed by an external signal processing unit provided in a semiconductor chip different from the solid-state imaging device 1, for example, a digital signal processor (DSP) circuit or the like.

The pixel array unit 11 has a configuration in which a plurality of pixels 21 are two-dimensionally arranged in a matrix in a row direction and a column direction. Here, the row direction refers to a pixel row of the pixel array unit 11, that is, an array direction in the horizontal direction, and the column direction refers to a pixel column of the pixel array unit 11, that is, an array direction in the vertical direction.

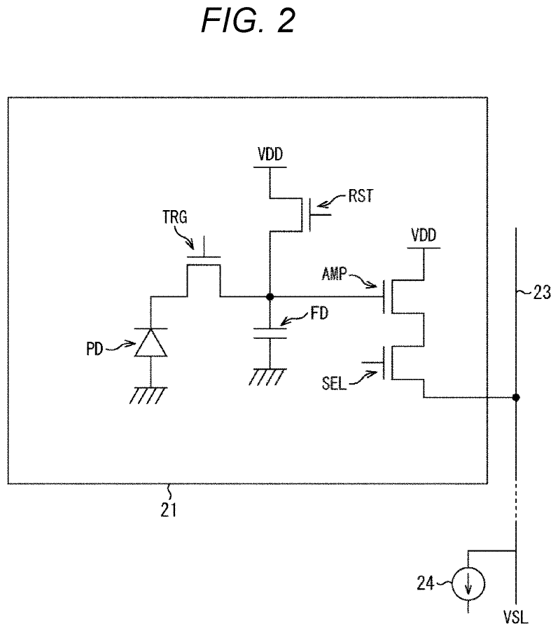

Each of the pixels 21 includes a photoelectric conversion unit that generates and accumulates charges according to an amount of received light, and a plurality of pixel transistors (so-called MOS transistors). Note that a specific circuit configuration example of the pixel 21 will be described later with reference to FIG. 2.

Furthermore, in the pixel array unit 11, a pixel drive wiring 22 as a row signal line is wired along the row direction for each pixel row, and a vertical signal line 23 as a column signal line is wired along the column direction for each pixel column. The pixel drive wiring 22 transmits a drive signal for driving when reading a signal from the pixel 21. In FIG. 1, the pixel drive wiring 22 is illustrated as one line, but the number is not limited to one. One end of the pixel drive wiring 22 is connected to an output terminal corresponding to each row of the vertical drive unit 12.

The vertical drive unit 12 includes a shift register, an address decoder, and the like and drives each pixel of the pixel array unit 11 at the same time for all the pixels, in units of rows, or the like. The vertical drive unit 12 constitutes a drive unit that controls the operation of each pixel of the pixel array unit 11 together with the system control unit 15. Although a specific configuration of the vertical drive unit 12 is not illustrated, the vertical drive unit generally includes two scanning systems of a reading scanning system and a sweeping scanning system.

In order to read a signal from the pixel 21, the reading scanning system sequentially selects and scans the pixel 21 of the pixel array unit 11 row by row. The signal read from the pixel 21 is an analog signal. The sweeping scanning system performs sweep scanning on a read row on which the read scanning is to be performed by the reading scanning system earlier than the read scanning by an exposure time.

By the sweep scanning by the sweeping scanning system, unnecessary charges are swept out from the photoelectric conversion units of the pixels 21 in the read row, whereby the photoelectric conversion units of the respective pixels 21 are reset. Then, by sweeping out (resetting) unnecessary charges by the sweeping scanning system, a so-called electronic shutter operation is performed. Here, the electronic shutter operation refers to operation of discharging the charge of the photoelectric conversion unit and newly starting exposure (starting accumulation of charges).

The signal read by the read operation of the reading scanning system corresponds to the amount of the received light after the immediately preceding read operation or electronic shutter operation. Then, the period from the read timing by the immediately preceding read operation or the sweep timing by the electronic shutter operation to the read timing by the current read operation is the exposure period in the pixel 21.

The signal output from each pixel 21 of the pixel row selectively scanned by the vertical drive unit 12 is input to the column processing unit 13 through each of the vertical signal lines 23 for each pixel column. The column processing unit 13 performs predetermined signal processing on the signal output from each pixel 21 of the selected row through the vertical signal line 23 for each pixel column of the pixel array unit 11, and temporarily holds the pixel signal after the signal processing.

Specifically, the column processing unit 13 performs, as signal processing, at least noise removal processing, for example, correlated double sampling (CDS) processing or double data sampling (DDS) processing. For example, in the CDS processing, fixed pattern noise unique to the pixel, such as reset noise or threshold variation of an amplification transistor in the pixel, is removed. The column processing unit 13 may have, for example, an analog-digital (AD) conversion function in addition to the noise removal processing, and convert an analog pixel signal into a digital signal and output the digital signal.

The horizontal drive unit 14 includes a shift register, an address decoder, and the like, and sequentially selects a unit circuit corresponding to the pixel column in the column processing unit 13. When the selective scanning is performed by the horizontal drive unit 14, the pixel signal subjected to the signal processing for every unit circuit in the column processing unit 13 is sequentially output.

The system control unit 15 includes a timing generator that generates various timing signals and the like, and performs drive control of the vertical drive unit 12, the column processing unit 13, the horizontal drive unit 14, and the like on the basis of various timings generated by the timing generator.

The signal processing unit 16 has at least an arithmetic processing function, and performs various signal processing such as arithmetic processing on the pixel signal output from the column processing unit 13. The data storage unit 17 temporarily stores data necessary for signal processing in the signal processing unit 16. The pixel signal subjected to the signal processing in the signal processing unit 16 is converted into a predetermined format and output from an output unit 18 to the outside of the device.

### 2. Configuration Example of Pixel Circuit

FIG. 2 is a diagram illustrating a circuit configuration example of one pixel 21 provided in the pixel array unit 11.

In this example, one pixel 21 is configured to include a photodiode PD, a transfer transistor TRG, a floating diffusion region FD, a reset transistor RST, an amplification transistor AMP, and a selection transistor SEL. The transfer transistor TRG, the reset transistor RST, the amplification transistor AMP, and the selection transistor SEL include, for example, an N-type MOS transistor (MOS FET).

The photodiode PD is a photoelectric conversion unit provided in the pixel 21, receives light from a subject, generates a charge corresponding to the amount of received light by photoelectric conversion, and accumulates the charge. The photodiode PD has an anode terminal grounded and a cathode terminal connected to the floating diffusion region FD via the transfer transistor TRG.

The transfer transistor TRG is provided between the photodiode PD and the floating diffusion region FD, and transfers the charge accumulated in the photodiode PD to the floating diffusion region FD when turned on by a transfer drive signal supplied to the gate.

The floating diffusion region FD is a voltage conversion unit that converts the charge transferred from the photodiode PD via the transfer transistor TRG into an electric signal, for example, a voltage signal, and outputs the electric signal. The floating diffusion region FD is also connected to the source of the reset transistor RST and the gate of the amplification transistor AMP.

When the reset transistor RST is turned on by a reset drive signal supplied to the gate, the charge accumulated in the floating diffusion region FD is discharged to the drain (constant voltage source VDD), and the potential of the floating diffusion region FD is reset.

The amplification transistor AMP outputs a pixel signal corresponding to the potential of the floating diffusion region FD. That is, the amplification transistor AMP constitutes a source follower circuit with a constant current source 24 connected via the vertical signal line 23, and a pixel signal VSL indicating a level according to the charge accumulated in the floating diffusion region FD is output from the amplification transistor AMP to the column processing unit 13 (FIG. 1) via the selection transistor SEL. The constant current source 24 is provided in the column processing unit 13, for example.

The selection transistor SEL is connected between the source of the amplification transistor AMP and the vertical signal line 23, and a selection drive signal is supplied to the gate of the selection transistor SEL. When the selection transistor SEL is turned on by the selection drive signal, the selection transistor SEL is brought into a conductive state, and the pixel 21 provided with the selection transistor SEL is brought into a selected state. When the pixel 21 is selected, the pixel signal VSL output from the amplification transistor AMP is read out to the column processing unit 13 via the vertical signal line 23.

The transfer drive signal, the reset drive signal, and the selection drive signal supplied to the gates of the transfer transistor TRG, the reset transistor RST, and the selection transistor SEL are transmitted from the vertical drive unit 12 via a row signal line corresponding to the pixel drive wiring 22 in FIG. 1. The transfer drive signal, the reset drive signal, and the selection drive signal are pulse signals in which a high-level state becomes an active state (on state) and a low-level state becomes an inactive state (off state).

The pixel 21 has the circuit configuration as described above.

Note that the circuit configuration of FIG. 2 is an example of a pixel circuit that can be used for the pixel array unit 11, and other circuit configurations can be used. For example, each pixel 21 may have a shared pixel structure in which a plurality of pixels shares a readout circuit. In a case where the shared pixel structure is adopted as the pixel circuit, for example, a configuration in which the floating diffusion region FD, the reset transistor RST, the amplification transistor AMP, and the selection transistor SEL are shared by four 2×2 pixels of two pixels in each of the row direction and the column direction, and the photodiode PD and the transfer transistor TRG are arranged in units of pixels can be adopted. Note that the number of pixels of the sharing unit is not limited to four pixels.

Hereinafter, the structure of the pixel 21 portion in the substrate vertical direction will be described.

### 3. First Embodiment of Pixel

First, a first embodiment using a dielectric multilayer film configured by alternately stacking two types of dielectric films having different refractive indexes in the pixel 21 will be described.

### <3.1 First Structure Example of Pixel According to First Embodiment>

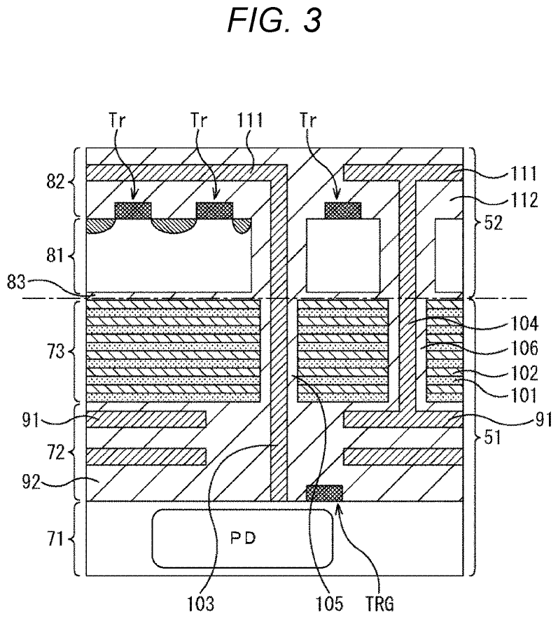

FIG. 3 is a cross-sectional view schematically illustrating a first structure example of the pixel 21 in the first embodiment.

The pixel 21 of the first structure example is configured by stacking two substrates of a first-layer pixel substrate 51 and a second-layer pixel substrate 52. A dashed-dotted line in FIG. 3 indicates a joint surface between the first-layer pixel substrate 51 and the second-layer pixel substrate 52.

The first-layer pixel substrate 51 is formed by stacking a semiconductor substrate 71, a wiring layer 72, and a dielectric multilayer film 73. The second-layer pixel substrate 52 is formed by stacking a semiconductor substrate 81, a wiring layer 82 formed on one surface of the semiconductor substrate 81, and an insulating film 83 formed on the other surface of the semiconductor substrate 81.

In the first-layer pixel substrate 51, the upper surface of the semiconductor substrate 71 on which the wiring layer 72 is formed is the front surface of the semiconductor substrate 71, and the surface opposite to the surface on which the wiring layer 72 is formed is the back surface of the semiconductor substrate 71, and is the light incident surface on which light is incident. On the back surface of the semiconductor substrate 71, a color filter layer, an on-chip lens, or the like can be formed as necessary.

In the second-layer pixel substrate 52, the upper surface of the semiconductor substrate 81 on which the wiring layer 82 is formed is the front surface of the semiconductor substrate 81, and the surface on which the insulating film 83 is formed is the back surface of the semiconductor substrate 81. Therefore, the first-layer pixel substrate 51 and the second-layer pixel substrate 52 are bonded together in a so-called face-to-back manner in which the front surface side of the semiconductor substrate 71 and the back surface side of the semiconductor substrate 81 are bonded together.

The semiconductor substrate 71 is a substrate using, for example, silicon (Si) as a semiconductor material. In the semiconductor substrate 71, a photodiode PD is formed in units of pixels, and a transfer transistor TRG is formed at an interface with the wiring layer 72. At least the transfer transistor TRG is provided in the first-layer pixel substrate 51, but other pixel transistors may also be formed. In FIG. 3, only the gate electrode of the transfer transistor TRG is illustrated.

The photodiode PD is configured, for example, by forming an N-type semiconductor region having a conductivity type different from the P-type in a P-type semiconductor region (P-well layer) constituting the semiconductor substrate 71. Furthermore, in the semiconductor substrate 71, for example, a pixel isolation portion or the like that electrically isolates a semiconductor region including the photodiode PD in the pixel from the adjacent pixel is formed at a boundary portion with the adjacent pixel, but is omitted in FIG. 3.

The wiring layer 72 includes one or more layers of wiring 91 and an interlayer insulating film 92. The wiring 91 is formed of, for example, a metal such as copper (Cu), tungsten (W), aluminum (Al), or gold (Au), or a material such as conductive polysilicon doped with boron (B), phosphorus (P), or the like at a high concentration. The interlayer insulating film 92 is formed of, for example, silicon oxide (SiO2) or the like. In the example of FIG. 3, the wiring 91 is formed in two layers in the wiring layer 72, but the wiring 91 may be formed in one layer or three or more layers.

The dielectric multilayer film 73 is configured by alternately stacking a first film 101 using a dielectric material having a first refractive index n₁ and a second film 102 using a dielectric material having a second refractive index n₂ (n₁>n₂) lower than the first refractive index n₁. Hereinafter, for the sake of simplicity, the first film 101 having a higher refractive index will be referred to as a high refractive index film 101, and the second film 102 having a lower refractive index will be referred to as a low refractive index film 102.

In the example of FIG. 3, the number of stacked layers of the high refractive index film 101 and the low refractive index film 102 alternately stacked is 12, but the dielectric multilayer film 73 may be configured by stacking at least three or more layers. The dielectric multilayer film 73 is formed on the entire light receiving region of the pixel array unit 11 in a planar direction. However, the dielectric multilayer film 73 is opened in a region where through electrodes 103 and 104 electrically connecting the first-layer pixel substrate 51 and the second-layer pixel substrate 52 are arranged.

The dielectric materials of the high refractive index film 101 and the low refractive index film 102 may be any materials that can be formed on a substrate by, for example, a chemical vapor deposition (CVD) method, a sputtering method, a plating method, or the like and can accurately control the film thickness at the time of film formation. Furthermore, it is desirable to use an insulating material in order to suppress short circuit defects between the through electrodes 103 and 104. As the dielectric material of the high refractive index film 101 and the low refractive index film 102, for example, a silicon compound such as SiOx, SiN, or SiC, polysilicon (polySi), amorphous silicon (a-Si), or a metal compound containing an oxide or a nitride such as TiO2, Al2O3, or TiN can be used. These dielectric materials have a high melting point and heat resistance.

Note that, in the present embodiment, the dielectric multilayer film 73 is configured by alternately stacking two types of films having different refractive indexes, but may be configured by stacking three or more types of films.

The semiconductor substrate 81 is a substrate including, for example, a P-type semiconductor region using, for example, silicon (Si) as a semiconductor material. A plurality of pixel transistors Tr is formed on a surface on the wiring layer 82 side, which is the front surface of the semiconductor substrate 81. The plurality of pixel transistors Tr are pixel transistors that are not provided in the first-layer pixel substrate 51. For example, in a case where the pixel transistor formed in the first-layer pixel substrate 51 is only the transfer transistor TRG, each of the reset transistor RST, the amplification transistor AMP, and the selection transistor SEL is formed as the pixel transistor Tr in the second-layer pixel substrate 52. Furthermore, for example, in a case where the transfer transistor TRG and the amplification transistor AMP are formed in the first-layer pixel substrate 51, each of the reset transistor RST and the selection transistor SEL is formed as the pixel transistor Tr in the second-layer pixel substrate 52.

The through electrode 103 penetrates the semiconductor substrate 81 and the dielectric multilayer film 73, and connects a predetermined wiring 111 of the second-layer pixel substrate 52 and a predetermined diffusion layer (not illustrated) of the semiconductor substrate 71 of the first-layer pixel substrate 51. The through electrode 103 and the dielectric multilayer film 73 are separated by an insulating film 105. The through electrode 104 penetrates the semiconductor substrate 81 and the dielectric multilayer film 73, and connects the predetermined wiring 111 of the second-layer pixel substrate 52 and the predetermined wiring 91 of the first-layer pixel substrate 51. The through electrode 104 and the dielectric multilayer film 73 are separated by an insulating film 106.

The wiring layer 82 includes one or more layers of wiring 111 and an interlayer insulating film 112. Although the number of layers of the wiring 111 is one in FIG. 3 for simplicity, a plurality of layers of the wiring 111 may be formed in the wiring layer 82. The wiring 111 is formed of, for example, a material such as copper (Cu), tungsten (W), aluminum (Al), or gold (Au). The interlayer insulating film 112 is formed of, for example, silicon oxide (SiO2) or the like.

The insulating film 83 formed on the back surface side (lower side in FIG. 3) of the semiconductor substrate 81 is formed of, for example, silicon oxide (SiO2) or the like.

As described above, solid-state imaging device 1 is configured by stacking first-layer pixel substrate 51 and second-layer pixel substrate 52. In the first-layer pixel substrate 51, at least a photodiode PD and a transfer transistor TRG provided for each pixel are formed. In the second-layer pixel substrate 52, another pixel transistor Tr not formed in the first-layer pixel substrate 51 is formed. In a case where there is only one pixel transistor Tr formed in the first-layer pixel substrate 51, the pixel transistor Tr is set as the transfer transistor TRG, and the reset transistor RST, the amplification transistor AMP, and the selection transistor SEL are formed in the second-layer pixel substrate 52.

In the first structure example of the pixel 21 of the first embodiment, the dielectric multilayer film 73 configured by stacking at least three layers of the high refractive index film 101 and the low refractive index film 102 is disposed between the semiconductor substrate 71 of the first-layer pixel substrate 51 and the semiconductor substrate 81 of the second-layer pixel substrate 52. The dielectric multilayer film 73 reflects light that is incident from the back surface (the lower surface in FIG. 3) of the semiconductor substrate 71 as a light incident surface, passes through the wiring layer 72, and is about to pass through to the second-layer pixel substrate 52.

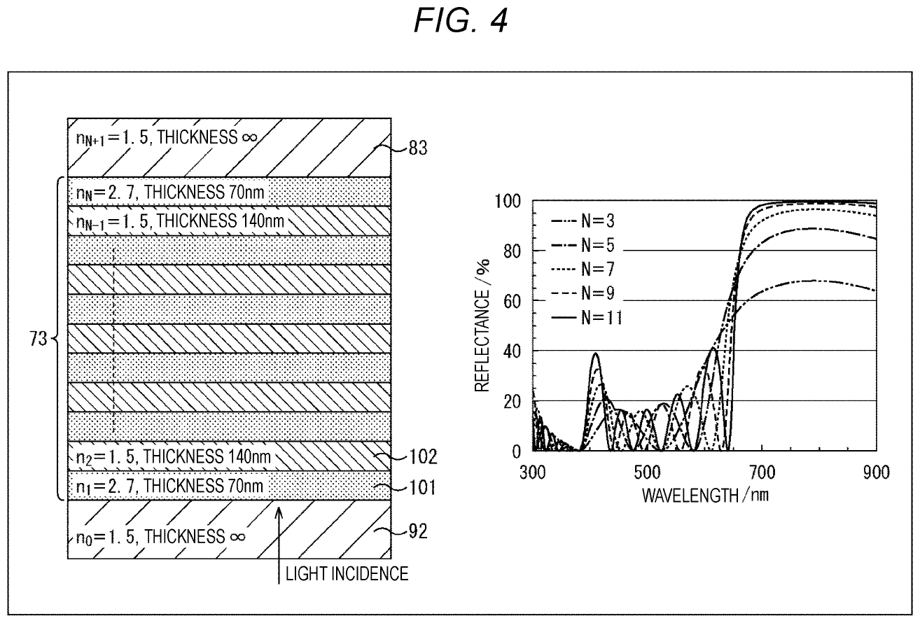

FIG. 4 illustrates a result of simply estimating the light reflectance of the dielectric multilayer film 73 using the effective Fresnel coefficient method.

The inventor has configured the dielectric multilayer film 73 with N layers (N>2) as illustrated in the laminated structure diagram on the left side of FIG. 4 by using titanium oxide (TiO2) as the high refractive index film 101 and using silicon oxide (SiO2) as the low refractive index film 102, and calculated the reflectance for each wavelength in a case where light is vertically incident. Note that it is assumed that the refractive index n does not depend on the wavelength. Furthermore, the film thickness of the high refractive index film 101 is 70 nm, and the refractive index n₁ of titanium oxide (TiO2) is about 2.7. The film thickness of the low refractive index film 102 is 140 nm, and the refractive index n₂ of silicon oxide (SiO2) is about 1.5. The upper and lower films of the dielectric multilayer film 73 were made of the same silicon oxide (SiO2) as the low refractive index film 102.

The graph on the right side of FIG. 4 illustrates a simulation result obtained by calculating the reflectance for each wavelength.

In the simulation result, high reflectance is obtained for light having a long wavelength, specifically, light of 730 nm or more, which is hardly absorbed by silicon and is easily transmitted to the second-layer pixel substrate 52. For example, a reflectance of about 98% is obtained when the number of layers N=9, and a reflectance of 99% or more is obtained when N=11. That is, it can be seen that an optical band gap is generated by controlling the combination of the film thickness and the refractive index, and the dielectric multilayer film 73 functions as a high reflectance mirror for light having a long wavelength. Note that the combination of the dielectric material and the film thickness of the high refractive index film 101 and the low refractive index film 102 is not limited thereto.

As described above, the dielectric multilayer film 73 can reflect light that is incident from the back surface (the lower surface in FIG. 3) of the semiconductor substrate 71 as a light incident surface, passes through the wiring layer 72, and is about to pass through to the second-layer pixel substrate 52. As a result, the transmittance of light to the second-layer pixel substrate 52 can be reduced, so that parasitic light reception sensitivity (PLS) in the second-layer pixel substrate 52 can be suppressed. Furthermore, since the dielectric material constituting the dielectric multilayer film 73 has heat resistance, a shield layer having both a shielding effect and heat resistance can be formed.

### <3.2 Manufacturing Method of First Structure Example of Pixel>

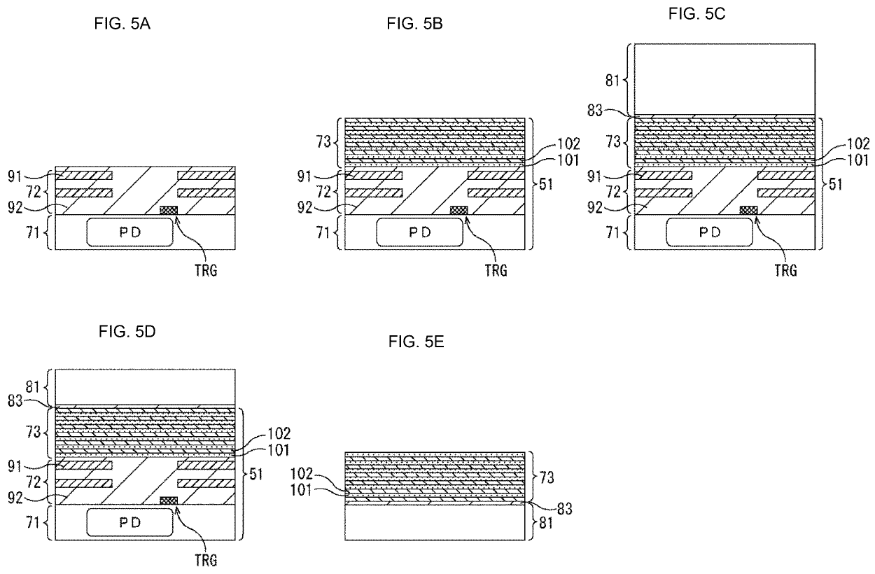

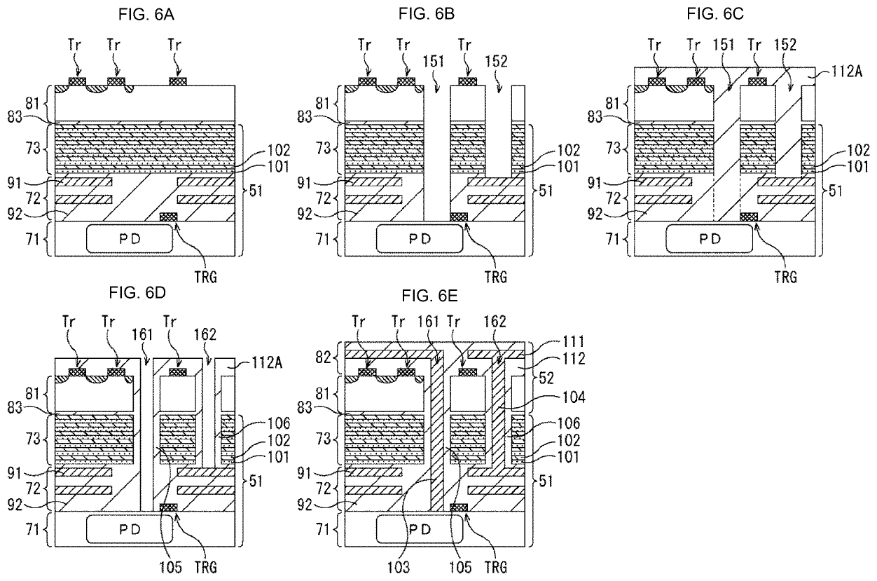

Next, a method of manufacturing the pixel 21 of the first structure example illustrated in FIG. 4 will be described with reference to FIGS. 5 and 6.

First, as illustrated in A of FIG. 5, after the photodiode PD is formed by forming an N-type semiconductor region on the semiconductor substrate 71 formed of a P-type semiconductor region, the transfer transistor TRG is formed. Then, the wiring 91 and the interlayer insulating film 92 are alternately stacked on the surface on which the transfer transistor TRG is formed using a dual damascene method or the like, thereby forming the wiring layer 72.

Next, as illustrated in B of FIG. 5, the dielectric multilayer film 73 is formed by alternately stacking the high refractive index film 101 and the low refractive index film 102 on the upper surface of the wiring layer 72. The number of stacked layers of the high refractive index film 101 and the low refractive index film 102 is 3 or more. As a method of forming the high refractive index film 101 and the low refractive index film 102, for example, a method capable of forming a film on a substrate and capable of accurately controlling the film thickness at the time of film formation, such as a CVD method, a sputtering method, or a plating method, is adopted. An insulating film for bonding to the semiconductor substrate 81 of the second-layer pixel substrate 52 may be further formed on the upper surface of the dielectric multilayer film 73.

With the state illustrated in B of FIG. 5, the first-layer pixel substrate 51 is completed.

Next, as illustrated in C of FIG. 5, the semiconductor substrate 81 in which the insulating film 83 is formed on one surface of the substrate is prepared. Then, after the insulating film 83 of the semiconductor substrate 81 and the dielectric multilayer film 73 of the first-layer pixel substrate 51 are bonded by, for example, plasma bonding or the like, the semiconductor substrate 81 is thinned as illustrated in D of FIG. 5. Note that, in a case where a silicon on insulator (SOI) substrate is used as the semiconductor substrate 81, the thinning process is omitted.

In the example described above, the dielectric multilayer film 73 is formed on the wiring layer 72 of the semiconductor substrate 71 on the first-layer pixel substrate 51 side. However, as illustrated in E of FIG. 5, the dielectric multilayer film 73 may be formed on the insulating film 83 of the semiconductor substrate 81 on the second-layer pixel substrate 52 side and bonded to the first-layer pixel substrate 51. In this case, the bonding surface between the first-layer pixel substrate 51 and the second-layer pixel substrate 52 is the surface where the dielectric multilayer film 73 and the wiring layer 72 are in contact with each other in the state illustrated in D of FIG. 5.

Next, as illustrated in A of FIG. 6, a plurality of pixel transistors Tr is formed on the upper surface (front surface) of the semiconductor substrate 81 bonded to the first-layer pixel substrate 51. These pixel transistors Tr correspond to, for example, the reset transistor RST, the amplification transistor AMP, the selection transistor SEL, or the like.

Next, as illustrated in B of FIG. 6, through holes 151 and 152 penetrating at least the semiconductor substrate 81 and the dielectric multilayer film 73 are formed. The through holes 151 and 152 correspond to regions where the through electrodes 103 and 104 are formed, respectively, and are formed by etching the semiconductor substrate 81, the dielectric multilayer film 73, the wiring layer 72, and the like. For example, the through hole 151 is formed to a depth reaching the semiconductor substrate 71 of the first-layer pixel substrate 51, and the through hole 152 is formed to a depth reaching the wiring 91 of the wiring layer 72 of the first-layer pixel substrate 51.

Next, as illustrated in C of FIG. 6, an insulating film 112A is formed inside the formed through holes 151 and 152 and above the surface of the semiconductor substrate 81 on which the pixel transistor Tr is formed, and then planarized.

Next, as illustrated in D of FIG. 6, dry etching or the like is performed from the upper surface of the insulating film 112A in regions corresponding to the through electrodes 103 and 104, thereby forming through holes 161 and 162. Portions of the insulating film 112A remaining on the outer circumferences of the through holes 161 and 162 correspond to the insulating films 105 and 106, respectively.

Next, as illustrated in E of FIG. 6, a metal material to be the through electrodes 103 and 104, for example, tungsten (W), copper (Cu), or the like is embedded in each of the formed through holes 161 and 162 by a dual damascene method or the like, and the wiring 111 connected to each of the through holes 161 and 162 is formed on the upper surface of the insulating film 112A.

Finally, an insulating film is formed on the upper surface of the wiring 111, and the wiring layer 82 including the wiring 111 and the interlayer insulating film 112 is formed, whereby the second-layer pixel substrate 52 is completed, and the pixel structure illustrated in FIG. 4 is completed.

According to the method for manufacturing the pixel 21 of the first structure example of the first embodiment described above, since the dielectric material constituting the dielectric multilayer film 73 has heat resistance, an active element such as the pixel transistor Tr can be formed in the second-layer pixel substrate 52 after the dielectric multilayer film 73 is formed. As a result, the degree of freedom of the process can be improved, and the solid-state imaging device 1 can be efficiently manufactured in a short time.

### <3.3 Second Structural Example of Pixel According to First Embodiment>

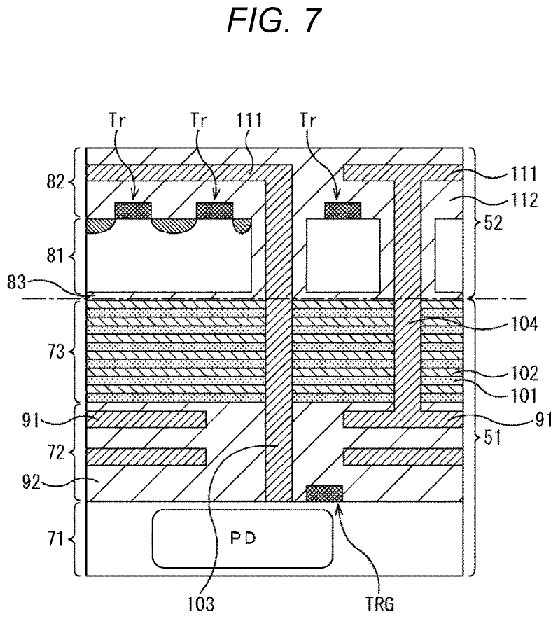

FIG. 7 is a cross-sectional view schematically illustrating a second structure example of the pixel 21 in the first embodiment.

In FIG. 7, parts corresponding to those in the first structure example illustrated in FIG. 3 are denoted by the same reference signs, and description of those parts will be omitted as appropriate, and description will be given focusing on different parts. The similarity applies to the third and subsequent structural examples described below.

In the first structural example illustrated in FIG. 3, the insulating films 105 and 106 are formed on the outer circumferences of the through electrodes 103 and 104, respectively.

On the other hand, in the second structure example of FIG. 7, the insulating film 105 is not formed on the outer circumference of the through electrode 103, and the through electrode 103 and the dielectric multilayer film 73 are configured to be in contact with each other. Similarly, in the through electrode 104, the insulating film 106 is not formed on the outer circumference of the through electrode 104, and the through electrode 104 and the dielectric multilayer film 73 are in contact with each other.

Other structures of the second structure example are similar to those of the first structure example described above.

According to the second structure example of the pixel 21 described above, since the insulating films 105 and 106 inserted between the through electrode 103 or 104 and the dielectric multilayer film 73 are omitted, entry of light into the second-layer pixel substrate 52 can be further prevented, so that the effect of suppressing parasitic light reception sensitivity in the second-layer pixel substrate 52 can be further enhanced.

### <3.4 Manufacturing Method of Second Structure Example of Pixel>

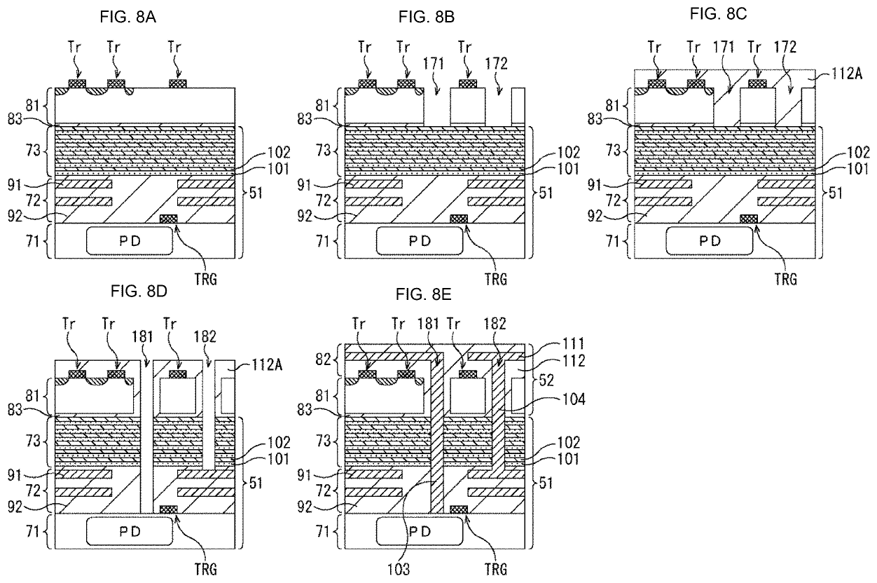

Next, a method of manufacturing the pixel 21 of the second structure example illustrated in FIG. 7 will be described with reference to FIG. 8.

The state illustrated in A of FIG. 8 is the same as the state in A of FIG. 6 described in the method of manufacturing the pixel 21 of the first structure example, and is formed similarly to the manufacturing method of the first structure example until this state. The state illustrated in A of FIG. 8 is a state in which the semiconductor substrate 81 and the first-layer pixel substrate 51 are bonded to each other after the first-layer pixel substrate 51 is formed, and the plurality of pixel transistors Tr are formed on the upper surface of the semiconductor substrate 81.

Next, as illustrated in B of FIG. 8, through holes 171 and 172 penetrating the semiconductor substrate 81 are formed. The through holes 171 and 172 correspond to regions where the through electrodes 103 and 104 are formed, respectively, and are formed to a depth reaching the dielectric multilayer film 73 of the first-layer pixel substrate 51.

Next, as illustrated in C of FIG. 8, an insulating film 112A is formed inside the formed through holes 171 and 172 and above the surface of the semiconductor substrate 81 on which the pixel transistor Tr is formed, and then planarized.

Next, as illustrated in D of FIG. 8, dry etching or the like is performed from the upper surface of the insulating film 112A in regions corresponding to the through electrodes 103 and 104, thereby forming through holes 181 and 182.

Next, as illustrated in E of FIG. 8, a metal material to be the through electrodes 103 and 104, for example, tungsten (W), copper (Cu), or the like is embedded in each of the formed through holes 181 and 182 by a dual damascene method or the like, and the wiring 111 connected to each of the through holes 181 and 182 is formed on the upper surface of the insulating film 112A.

Finally, an insulating film is formed on the upper surface of the wiring 111, and the wiring layer 82 including the wiring 111 and the interlayer insulating film 112 is formed, whereby the second-layer pixel substrate 52 is completed, and the pixel structure illustrated in FIG. 7 is completed.

Also in the method of manufacturing the pixel 21 of the second structure example of the first embodiment described above, after the dielectric multilayer film 73 is formed, an active element such as the pixel transistor Tr can be formed on the second-layer pixel substrate 52. As a result, the degree of freedom of the process can be improved, and the solid-state imaging device 1 can be efficiently manufactured in a short time.

### <3.5 Third Structure Example of Pixel According to First Embodiment>

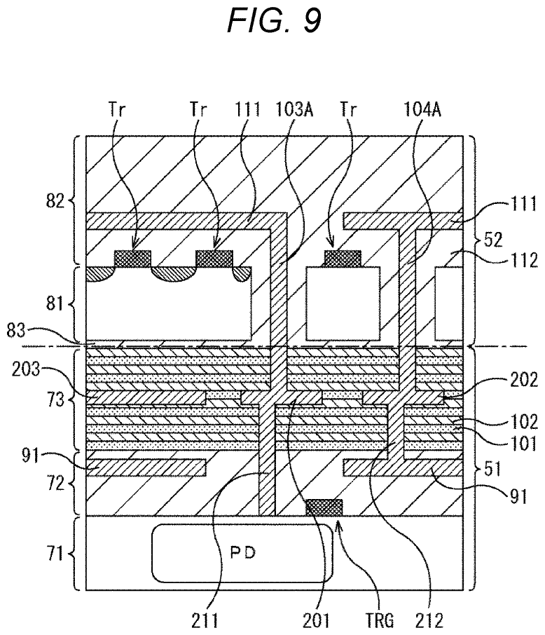

FIG. 9 is a cross-sectional view schematically illustrating a third structure example of the pixel 21 in the first embodiment.

The third structure example of FIG. 9 is different from the first structure example illustrated in FIG. 3 in that wirings 201 to 203 are embedded at predetermined depth positions in the dielectric multilayer film 73. Thus, the through electrode 103 in the first structure example of FIG. 3 is changed to a through electrode 103A. The through electrode 103A penetrates the semiconductor substrate 81 and is connected to the wiring 201. Similarly, the through electrode 104 in the first structure example of FIG. 3 is changed to a through electrode 104A. The through electrode 104A penetrates the semiconductor substrate 81 and is connected to the wiring 202.

In the layer of the dielectric multilayer film 73, the insulating film 105 is not formed on the outer circumference of the through electrode 103A, and the through electrode 103A and the dielectric multilayer film 73 are in contact with each other. Similarly, in the through electrode 104A, the insulating film 106 is not formed on the outer circumference of the through electrode 104A, and the through electrode 104A and the dielectric multilayer film 73 are in contact with each other.

The wiring 201 is also connected to a predetermined diffusion layer (not illustrated) of the semiconductor substrate 71 by a contact wiring 211. The wiring 202 is also connected to a predetermined wiring 91 in the wiring layer 72 by a contact wiring 212.

Other structures of the third structure example are similar to those of the first structure example described above.

According to the third structure example of the pixel 21 described above, similarly to the first structure example, the dielectric multilayer film 73 is arranged between the semiconductor substrate 81 of the second-layer pixel substrate 52 and the semiconductor substrate 71 of the first-layer pixel substrate 51, so that the effect of suppressing the parasitic light reception sensitivity and the electromagnetic shielding effect can be exhibited.

Furthermore, since the aspect ratio of the through electrodes 103A and 104A is reduced by providing the wirings 201 to 203 in the dielectric multilayer film 73, the difficulty of forming the through electrodes can be reduced. Moreover, since the diameters of the through electrodes 103A and 104A can be reduced, the area efficiency can be improved, and the total thickness of the solid-state imaging device 1 as a whole can be reduced.

### <3.6 Manufacturing Method of Third Structure Example of Pixel>

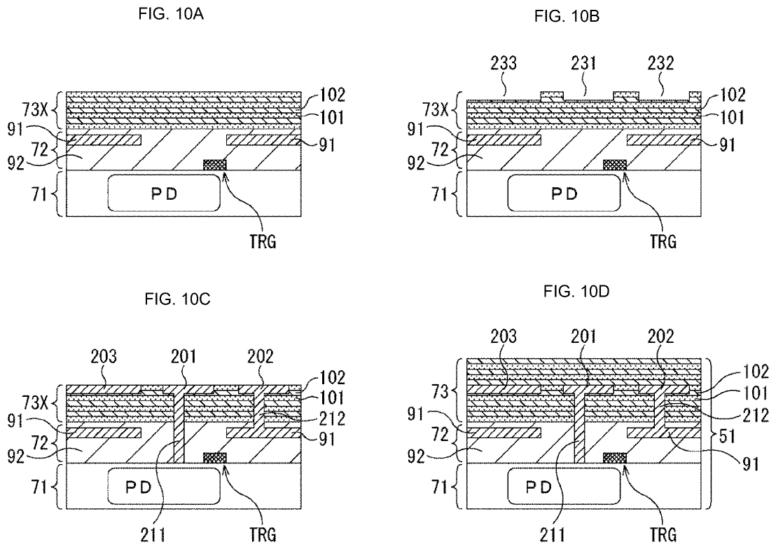

Next, a method of manufacturing the pixel 21 of the third structure example illustrated in FIG. 9 will be described with reference to FIG. 10.

As illustrated in A of FIG. 10, the dielectric multilayer film 73X corresponding to a part of the finally formed dielectric multilayer film 73 is formed on the wiring layer 72 of the semiconductor substrate 71 on which the photodiode PD and the transfer transistor TRG are formed. In the example of A of FIG. 8, the final entire dielectric multilayer film 73 is formed with 12 layers, whereas the dielectric multilayer film 73X is formed with 7 layers.

Next, as illustrated in B of FIG. 10, the regions of the dielectric multilayer film 73X where the wirings 201 to 203 are formed are etched to form dug portions 231 to 233.

Next, as illustrated in C of FIG. 10, the contact wirings 211 and 212 and the wirings 201 to 203 are formed using a dual damascene method or the like.

Next, as illustrated in D of FIG. 10, the remaining high refractive index films 101 and low refractive index films 102 are alternately formed on the upper surface of the layer on which the wirings 201 to 203 are formed, and the first-layer pixel substrate 51 is completed.

The process after forming the first-layer pixel substrate 51 is similar to the manufacturing method of the first structure example described above. Specifically, processes similar to the processes from the process in C of FIG. 5 to the process in E of FIG. 6 are executed.

Also in the method of manufacturing the pixel 21 of the third structure example described above, after the dielectric multilayer film 73 is formed, an active element such as the pixel transistor Tr can be formed on the second-layer pixel substrate 52. As a result, the degree of freedom of the process can be improved, and the manufacturing can be efficiently performed in a short time.

### <3.7 Fourth Structure Example of Pixel According to First Embodiment>

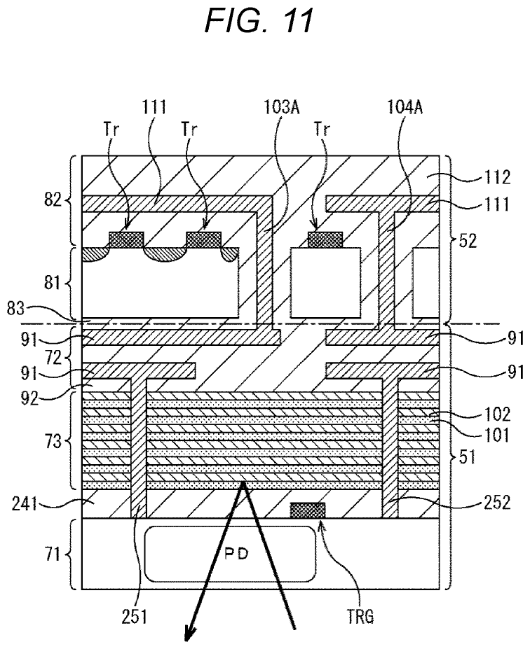

FIG. 11 is a cross-sectional view schematically illustrating a fourth structure example of the pixel 21 in the first embodiment.

In the first structure example illustrated in FIG. 3, in the first-layer pixel substrate 51, the wiring layer 72 is formed on the semiconductor substrate 71, and the dielectric multilayer film 73 is formed on the wiring layer 72. In other words, the wiring layer 72 is disposed between the semiconductor substrate 71 and the dielectric multilayer film 73.

On the other hand, in the fourth structure example in FIG. 11, in the first-layer pixel substrate 51, the dielectric multilayer film 73 is formed on the semiconductor substrate 71 via an insulating film 241, and the wiring layer 72 is formed on the dielectric multilayer film 73. In other words, the dielectric multilayer film 73 is disposed between the semiconductor substrate 71 and the wiring layer 72. The insulating film 241 is inserted between the dielectric multilayer film 73 and the semiconductor substrate 71.

The through electrodes 103 and 104 in the first structure example of FIG. 3 are changed to through electrodes 103A and 104A in FIG. 11. The through electrodes 103A are common in that they penetrate the semiconductor substrate 81 of the second-layer pixel substrate 52 and are connected to the predetermined wiring 91 of the wiring layer 72, but in the fourth structure example, since the wiring layer 72 is disposed closer to the second-layer pixel substrate 52 than the dielectric multilayer film 73, the aspect ratio of the through electrodes 103A and 104A is lower than that of the through electrodes 103 and 104 of the first structure example.

In the fourth structure example, through electrodes 251 and 252 penetrating the dielectric multilayer film 73 of the first-layer pixel substrate 51 are provided. The through electrodes 251 and 252 connect the wiring 91 different from the wiring 91 to which the through electrodes 103A and 104A are connected, and the semiconductor substrate 71 of the first-layer pixel substrate 51, respectively.

Other structures of the fourth structure example are similar to those of the first structure example described above.

According to the fourth structure example of the pixel 21 described above, similarly to the first structure example, the dielectric multilayer film 73 is disposed between the semiconductor substrate 81 of the second-layer pixel substrate 52 and the semiconductor substrate 71 of the first-layer pixel substrate 51, so that the effect of suppressing the parasitic light reception sensitivity and the electromagnetic shielding effect can be exhibited.

Furthermore, in the fourth structure example, since the aspect ratio of the through electrodes 103A and 104A is reduced, the diameter can be reduced, so that the area efficiency can be improved. Furthermore, the difficulty of formation of the through electrode can be reduced.

Moreover, since the dielectric multilayer film 73 is arranged at a position closer to the semiconductor substrate 71 of the first-layer pixel substrate 51, reflection by the dielectric multilayer film 73 occurs at a position closer to the semiconductor substrate 71 as indicated by an arrow in FIG. 11, so that it is possible to prevent light leakage to adjacent pixels and prevent color mixing.

### <3.8 Fifth Structure Example of Pixel According to First Embodiment>

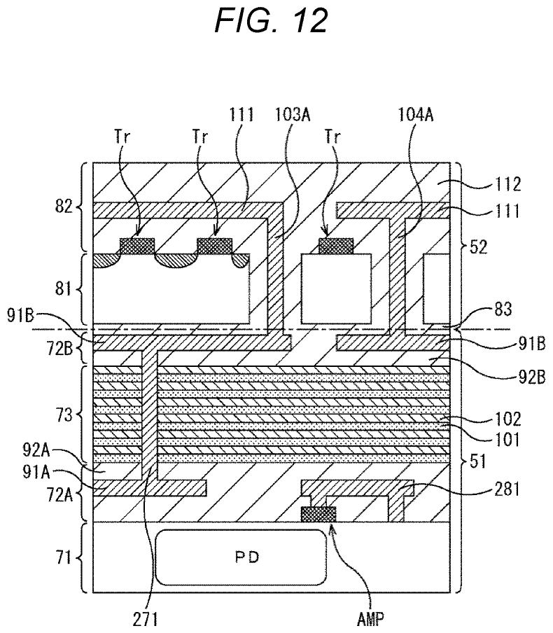

FIG. 12 is a cross-sectional view schematically illustrating a fifth structure example of the pixel 21 in the first embodiment.

In the fourth structure example illustrated in FIG. 11, as compared with the first structure example in FIG. 3, the arrangement of the wiring layer 72 and the dielectric multilayer film 73 of the first-layer pixel substrate 51 is interchanged, and the dielectric multilayer film 73 is formed between the semiconductor substrate 71 and the wiring layer 72.

On the other hand, in the fifth structure example in FIG. 12, a first wiring layer 72A and a second wiring layer 72B are formed on the first-layer pixel substrate 51, and the dielectric multilayer film 73 is formed between the first wiring layer 72A and the second wiring layer 72B. The first wiring layer 72A includes one or more layers of wiring 91A and an interlayer insulating film 92A, and is disposed between the semiconductor substrate 71 and the dielectric multilayer film 73. The second wiring layer 72B includes one or more layers of wiring 91B and an interlayer insulating film 92B, and is formed between the dielectric multilayer film 73 and the semiconductor substrate 81 of the second-layer pixel substrate 52.

The through electrode 103A connects the predetermined wiring 111 of the second-layer pixel substrate 52 and the predetermined wiring 91B of the second wiring layer 72B of the first-layer pixel substrate 51. The through electrode 104A connects the predetermined wiring 111 of the second-layer pixel substrate 52 and the predetermined wiring 91B of the second wiring layer 72B of the first-layer pixel substrate 51. The wirings 111 and 91B to which the through electrode 104A is connected are different from the wirings 111 and 91B to which the through electrode 103A is connected.

The first-layer pixel substrate 51 is provided with a through electrode 271 penetrating the dielectric multilayer film 73. The through electrode 271 connects the predetermined wiring 91A of the first wiring layer 72A and the predetermined wiring 91B of the second wiring layer 72B.

In the fifth structure example, not only the transfer transistor TRG but also the amplification transistor AMP is formed as the pixel transistor on the first-layer pixel substrate 51 side. In FIG. 12, the transfer transistor TRG is not illustrated, and the amplification transistor AMP is illustrated. A gate electrode of the amplification transistor AMP is connected to a floating diffusion region FD (not illustrated) formed in the semiconductor substrate 71 by a predetermined wiring 281 formed in the first wiring layer 72A.

Other structures of the fifth structure example are similar to those of the fourth structure example described above.

According to the fifth structure example of the pixel 21 described above, similarly to the fourth structure example, the dielectric multilayer film 73 is disposed between the semiconductor substrate 81 of the second-layer pixel substrate 52 and the semiconductor substrate 71 of the first-layer pixel substrate 51, so that the effect of suppressing the parasitic light reception sensitivity and the electromagnetic shielding effect can be exhibited.

Furthermore, in the fifth structure example, since the aspect ratio of the through electrodes 103A and 104A is reduced, the diameter can be reduced, so that the area efficiency can be improved. Furthermore, the difficulty of formation of the through electrode can be reduced.

Moreover, since not only the transfer transistor TRG but also the amplification transistor AMP is disposed on the first-layer pixel substrate 51 side, the wiring length of the wiring 281 between the floating diffusion region FD formed in the semiconductor substrate 71 and the gate electrode of the amplification transistor AMP can be shortened, so that the photoelectric conversion efficiency can be increased.

### <3.9 Sixth Structure Example of Pixel According to First Embodiment>

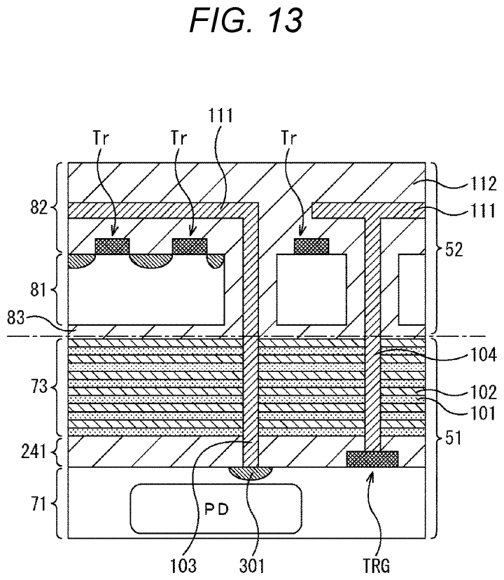

FIG. 13 is a cross-sectional view schematically illustrating a sixth structure example of the pixel 21 in the first embodiment.

In the sixth structure example of FIG. 13, the wiring layer 72 formed on the first-layer pixel substrate 51 in the first structure example illustrated in FIG. 3 is replaced with an insulating film 241. That is, in the sixth structure example, the first-layer pixel substrate 51 does not include the wiring layer 72, and the insulating film 241 is disposed between the semiconductor substrate 71 and the dielectric multilayer film 73.

The through electrode 103 penetrates the semiconductor substrate 81 and the dielectric multilayer film 73, and connects the predetermined wiring 111 of the second-layer pixel substrate 52 and a diffusion layer 301 of the semiconductor substrate 71 of the first-layer pixel substrate 51. The insulating film 105 is not formed between the through electrode 103 and the dielectric multilayer film 73, and the through electrode 103 and the dielectric multilayer film 73 are in contact with each other.

The through electrode 104 penetrates the semiconductor substrate 81 and the dielectric multilayer film 73, and connects the predetermined wiring 111 of the second-layer pixel substrate 52 and the gate electrode of the transfer transistor TRG of the first-layer pixel substrate 51. The insulating film 106 is not formed between the through electrode 104 and the dielectric multilayer film 73, and the through electrode 104 and the dielectric multilayer film 73 are in contact with each other.

Other structures of the sixth structure example are similar to those of the first structure example described above.

According to the sixth structure example of the pixel 21 described above, similarly to the first structure example, the dielectric multilayer film 73 is arranged between the semiconductor substrate 81 of the second-layer pixel substrate 52 and the semiconductor substrate 71 of the first-layer pixel substrate 51, so that the effect of suppressing the parasitic light reception sensitivity and the electromagnetic shielding effect can be exhibited.

Furthermore, the dielectric multilayer film 73 and the insulating film 241 are provided between the semiconductor substrate 81 of the second-layer pixel substrate 52 and the semiconductor substrate 71 of the first-layer pixel substrate 51, and the wiring layer 72 is omitted, so that the total thickness of the solid-state imaging device 1 as a whole can be reduced.

### <3.10 Seventh Structure Example of Pixel According to First Embodiment>

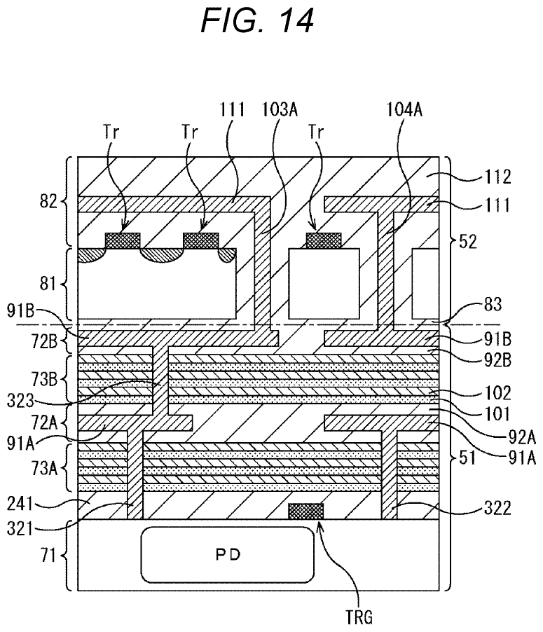

FIG. 14 is a cross-sectional view schematically illustrating a seventh structure example of the pixel 21 in the first embodiment.

In the seventh structure example in FIG. 14, the insulating film 241 is formed on the semiconductor substrate 71 of the first-layer pixel substrate 51, the first dielectric multilayer film 73A and the first wiring layer 72A are formed on the insulating film 241, and the second dielectric multilayer film 73B and the second wiring layer 72B are formed on the first wiring layer 72A. The second wiring layer 72B of the first-layer pixel substrate 51 and the insulating film 83 on the back surface of the semiconductor substrate 81 of the second-layer pixel substrate 52 are bonded.

That is, the dielectric multilayer film 73 formed of one layer in the above-described first structural example and the like is changed to two layers of the first dielectric multilayer film 73A and the second dielectric multilayer film 73B in the seventh structural example of FIG. 14. Furthermore, the wiring layer 72 formed of one layer in the above-described first structural example and the like is changed to two layers of a first wiring layer 72A and a second wiring layer 72B in the seventh structural example of FIG. 14. The first dielectric multilayer film 73A is disposed between the semiconductor substrate 71 and the first wiring layer 72A, and the second dielectric multilayer film 73B is disposed between the first wiring layer 72A and the second wiring layer 72B. Each of the first dielectric multilayer film 73A and the second dielectric multilayer film 73B is configured by stacking at least three or more layers of the high refractive index film 101 and the low refractive index film 102.

The through electrode 103A connects the predetermined wiring 111 of the second-layer pixel substrate 52 and the predetermined wiring 91B of the second wiring layer 72B of the first-layer pixel substrate 51. The through electrode 104A connects the predetermined wiring 111 of the second-layer pixel substrate 52 and the predetermined wiring 91B of the second wiring layer 72B of the first-layer pixel substrate 51. The wirings 111 and 91B to which the through electrode 104A is connected are different from the wirings 111 and 91B to which the through electrode 103A is connected.

A through electrode 321 penetrating the first dielectric multilayer film 73A connects a predetermined diffusion layer (not illustrated) of the semiconductor substrate 71 of the first-layer pixel substrate 51 and a predetermined wiring 91A of the first wiring layer 72A. An insulating film is not formed between the through electrode 321 and the first dielectric multilayer film 73A, and the through electrode 321 and the first dielectric multilayer film 73A are in contact with each other.

A through electrode 322 penetrating the first dielectric multilayer film 73A connects a predetermined diffusion layer (not illustrated) of the semiconductor substrate 71 of the first-layer pixel substrate 51 and a predetermined wiring 91A of the first wiring layer 72A. An insulating film is not formed between the through electrode 322 and the first dielectric multilayer film 73A, and the through electrode 322 and the first dielectric multilayer film 73A are in contact with each other. The wiring 91A connected to the through electrode 321 is different from the wiring 91A connected to the through electrode 322.

A through electrode 323 penetrating the second dielectric multilayer film 73B connects the predetermined wiring 91A of the first wiring layer 72A and the predetermined wiring 91B of the second wiring layer 72B. An insulating film is not formed between the through electrode 323 and the second dielectric multilayer film 73B, and the through electrode 323 and the second dielectric multilayer film 73B are in contact with each other.

Other structures of the seventh structure example are similar to those of the first structure example described above.

According to the seventh structure example of the pixel 21 described above, similarly to the first structure example, by arranging the two layers of the first dielectric multilayer film 73A and the second dielectric multilayer film 73B between the semiconductor substrate 81 of the second-layer pixel substrate 52 and the semiconductor substrate 71 of the first-layer pixel substrate 51, it is possible to exhibit the effect of suppressing the parasitic light reception sensitivity and the electromagnetic shielding effect.

In the seventh structure example, since the dielectric multilayer film is divided into two layers of the first dielectric multilayer film 73A and the second dielectric multilayer film 73B, the aspect ratio of the through electrodes 321 to 323 penetrating the first dielectric multilayer film 73A and the second dielectric multilayer film 73B is reduced. As a result, since the diameters of the through electrodes 321 to 323 can be reduced, the area efficiency can be improved. Furthermore, the difficulty of formation of the through electrode can be reduced.

### <3.11 Eighth Structure Example of Pixel According to First Embodiment>

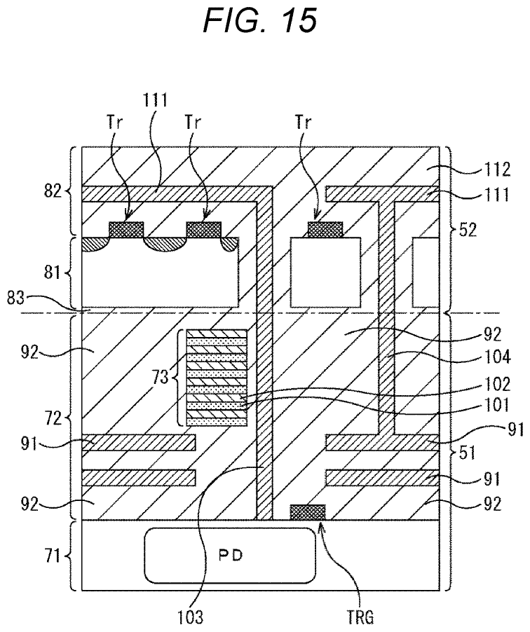

FIG. 15 is a cross-sectional view schematically illustrating an eighth structure example of the pixel 21 in the first embodiment.

In the first structure example illustrated in FIG. 3, the dielectric multilayer film 73 is formed on the entire light receiving region of the pixel array unit 11.

On the other hand, in the eighth structure example in FIG. 15, the dielectric multilayer film 73 is formed only in a part of each pixel 21 of the pixel array unit 11 in the planar direction, more specifically, in a region where light incidence is desired to be suppressed in each pixel 21. Examples of the region where light incidence is desired to be suppressed include a region corresponding to the diffusion layer formed on the semiconductor substrate 81 of the second-layer pixel substrate 52. As compared with the first structure example formed on the entire light receiving region, the interlayer insulating film 92 of the wiring layer 72 is formed in a region where the dielectric multilayer film 73 is not formed.

Other structures of the eighth structure example are similar to those of the first structure example described above.

According to the eighth structure example of the pixel 21 described above, similarly to the first structure example, since the dielectric multilayer film 73 is arranged in the region where light incidence between the semiconductor substrate 81 of the second-layer pixel substrate 52 and the semiconductor substrate 71 of the first-layer pixel substrate 51 is to be suppressed, it is possible to exhibit the effect of suppressing parasitic light reception sensitivity and the electromagnetic shielding effect.

The dielectric multilayer film 73 is not disposed in a region where light incidence does not need to be suppressed, and light is not reflected (transmitted to the semiconductor substrate 81 of the second-layer pixel substrate 52). As a result, it is possible to prevent light from leaking into adjacent pixels and to prevent color mixing.

### <3.12 Ninth Structure Example of Pixel According to First Embodiment>

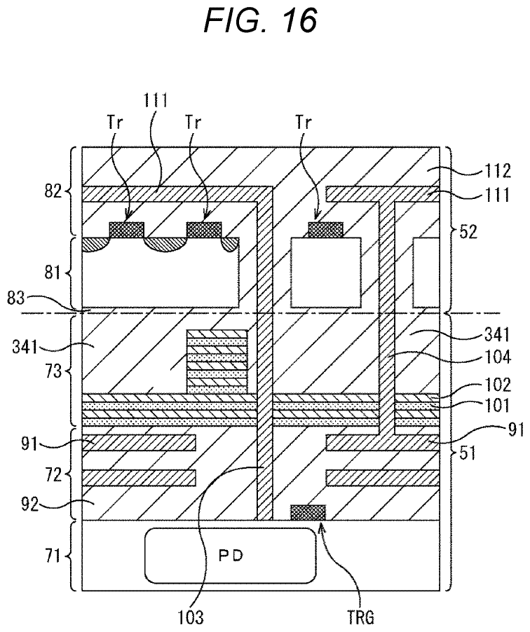

FIG. 16 is a cross-sectional view schematically illustrating a ninth structure example of the pixel 21 in the first embodiment.

The ninth structure example in FIG. 16 corresponds to a modification of the eighth structure example illustrated in FIG. 15.

In the eighth structure example illustrated in FIG. 15, the dielectric multilayer film 73 is formed only in a part of the light receiving region of the pixel array unit 11 in the planar direction, more specifically, in a region where light incidence is desired to be suppressed in each pixel 21 of the pixel array unit 11. The interlayer insulating film 92 is formed in a region where light incidence does not need to be suppressed.

On the other hand, in the ninth structure example in FIG. 16, the number of stacked dielectric multilayer films 73 is different between the region where light incidence of each pixel 21 is desired to be suppressed and the region where light incidence does not need to be suppressed, and the dielectric multilayer film 73 has two regions of different numbers of stacked layers in the planar direction. In a region where light incidence of each pixel 21 does not need to be suppressed, the dielectric multilayer film 73 is formed with a smaller number of stacked layers (four layers in this example) than in a region where light incidence needs to be suppressed. By forming an insulating film 341 in a region on the dielectric multilayer film 73 formed with a smaller number of stacked layers than a region where light incidence is to be suppressed, a step due to a difference in the number of stacked layers is filled.

Other structures of the ninth structure example are similar to those of the first structure example described above.

According to the ninth structure example of the pixel 21 described above, similarly to the first structure example, since the dielectric multilayer film 73 is arranged in the region where light incidence between the semiconductor substrate 81 of the second-layer pixel substrate 52 and the semiconductor substrate 71 of the first-layer pixel substrate 51 is to be suppressed, it is possible to exhibit the effect of suppressing parasitic light reception sensitivity and the electromagnetic shielding effect.

In a region where light incidence does not need to be suppressed, the dielectric multilayer film 73 is arranged with a smaller number of stacked layers than in a region where light incidence needs to be suppressed. As a result, it is possible to prevent light from leaking into adjacent pixels and to prevent color mixing.

### <3.13 Manufacturing Method of Eighth Structure Example and Ninth Structure Example of Pixel>

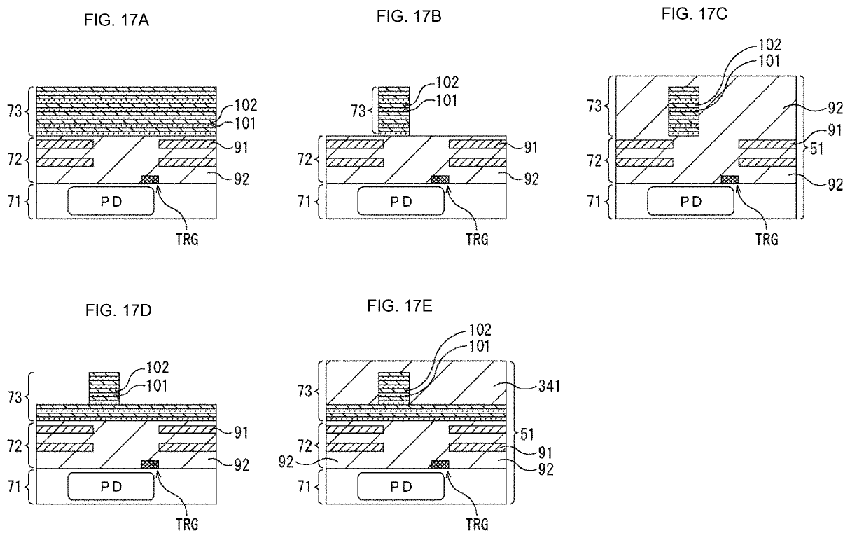

Next, a method of manufacturing the pixel 21 in the eighth structure example in FIG. 15 and the ninth structure example in FIG. 16 will be described with reference to FIG. 17.

First, a method of manufacturing the pixel 21 in the eighth structure example in FIG. 15 will be described.

The state illustrated in A of FIG. 17 is the same as the state of B of FIG. 5 described in the method of manufacturing the pixel 21 of the first structure example, and is formed similarly to the manufacturing method of the first structure example until this state. The state illustrated in A of FIG. 17 is a state in which the wiring layer 72 and the dielectric multilayer film 73 are formed on the semiconductor substrate 71 of the first-layer pixel substrate 51. The number of stacked layers of the high refractive index film 101 and the low refractive index film 102 of the dielectric multilayer film 73 is, for example, 12.

Next, as illustrated in B of FIG. 17, the dielectric multilayer film 73 other than the region where light incidence of each pixel 21 is desired to be suppressed is removed by dry etching or the like. As illustrated in C of FIG. 17, the interlayer insulating film 92 is further laminated on the removed region by using, for example, a CVD method. The interlayer insulating film 92 is also formed on the upper surface of the dielectric multilayer film 73 and planarized to form the first-layer pixel substrate 51.

After the first-layer pixel substrate 51 is formed, it can be manufactured similarly to the method of manufacturing the pixel 21 of the first structure example. Specifically, the processes after C of FIG. 5 described in the first structure example are executed. For example, in the process in C of FIG. 5, the interlayer insulating film 92 of the wiring layer 72 of the first-layer pixel substrate 51 and the insulating film 83 of the semiconductor substrate 81 on the second-layer pixel substrate 52 side are bonded. After the semiconductor substrate 81 on the second-layer pixel substrate 52 side is bonded, the plurality of pixel transistors Tr, the through electrodes 103 and 104, and the like are formed, and the pixel 21 of the eighth structural example is completed.

In the case of manufacturing the pixel 21 in the ninth structure example in FIG. 16, the process illustrated in D of FIG. 17 is executed from the state illustrated in A of FIG. 17 in which the dielectric multilayer films 73 of the number of stacked layers capable of sufficiently suppressing light incidence are formed on the entire surface of the wiring layer 72.

In the process illustrated in D of FIG. 17, a part of the dielectric multilayer film 73 other than the region where light incidence of each pixel 21 is desired to be suppressed is partially removed by dry etching or the like. For example, the upper eight layers of the 12 layers of the high refractive index film 101 and the low refractive index film 102 alternately stacked as the dielectric multilayer film 73 are removed in a region other than the region where light incidence is to be suppressed. As illustrated in E of FIG. 17, the insulating film 341 is formed in the removed region by, for example, a plasma CVD method. The insulating film 341 is also formed on the upper surface of the dielectric multilayer film 73 formed of 12 layers and planarized to form the first-layer pixel substrate 51.

After the first-layer pixel substrate 51 is formed, it can be manufactured similarly to the method of manufacturing the pixel 21 of the first structure example. Specifically, the processes after C of FIG. 5 described in the first structure example are executed. For example, the insulating film 341 on the upper surface of the dielectric multilayer film 73 of the first-layer pixel substrate 51 and the insulating film 83 of the semiconductor substrate 81 on the second-layer pixel substrate 52 side are bonded. After the bonding, the plurality of pixel transistors Tr, the through electrodes 103 and 104, and the like are formed, and the pixel 21 of the ninth structure example is completed.

Also in the method of manufacturing the pixel 21 according to the eighth structure example and the ninth structure example of the first embodiment described above, since the active element such as the pixel transistor Tr can be formed on the second-layer pixel substrate 52 after the dielectric multilayer film 73 is formed, the degree of freedom of the process can be improved, and the solid-state imaging device 1 can be efficiently manufactured in a short time.

### 4. Summary of Pixels According to First Embodiment

The pixel 21 according to the first embodiment described above is configured by stacking a first-layer pixel substrate 51 (first substrate) including a semiconductor substrate 71 on which at least photodiodes PD provided in pixel units are formed and a second-layer pixel substrate 52 (second substrate) including a semiconductor substrate 81 on which active elements such as pixel transistors Tr are formed. Furthermore, the pixel 21 includes the dielectric multilayer film 73 in a region between the semiconductor substrate 81 of the second-layer pixel substrate 52 and the semiconductor substrate 71 of the first-layer pixel substrate 51 and in which at least light incidence of each pixel 21 is desired to be suppressed. Since the dielectric material constituting the dielectric multilayer film 73 has heat resistance, a shield layer having both a shielding effect and heat resistance can be formed by the dielectric multilayer film 73. That is, parasitic light reception sensitivity in the second-layer pixel substrate 52 can be suppressed.

### 5. Second Embodiment of Pixel

Next, a second embodiment in which a shield layer is formed using a structure different from the dielectric multilayer film 73 in the pixel 21 will be described.

In the second embodiment, a pixel structure capable of suppressing parasitic light reception sensitivity in a second-layer pixel substrate by providing a shield layer on a semiconductor substrate is adopted.

### <5.1 First Structure Example of Pixel According to Second Embodiment>

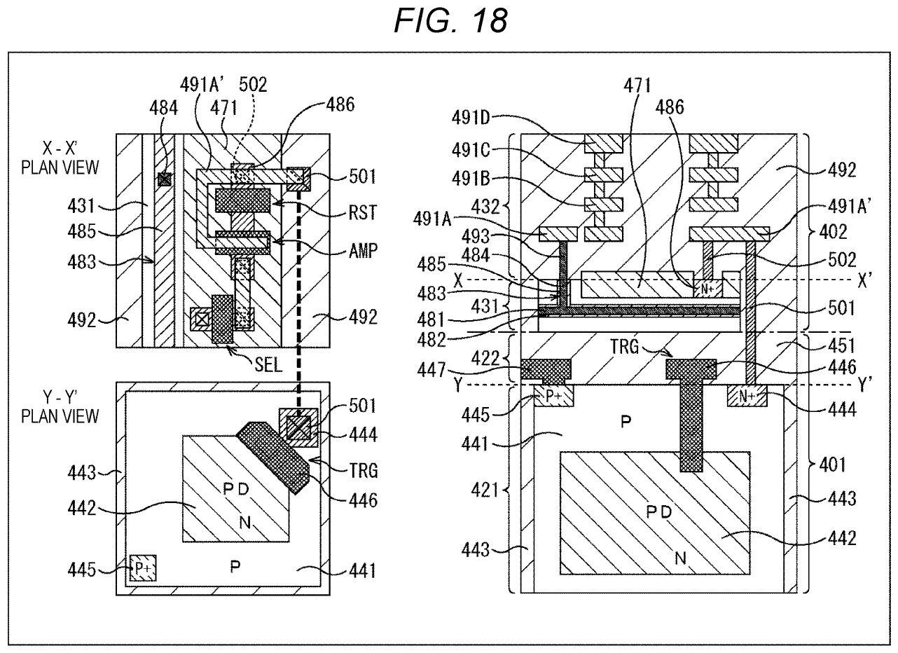

FIG. 18 is a diagram schematically illustrating a first structure example of the pixel 21 according to the second embodiment.

A cross-sectional view of the pixel 21 of the first structure example is illustrated on the right side of FIG. 18, and a plan view (Hereinafter, it is referred to as an X-X′ plan view.) taken along line X-X′ and a plan view (Hereinafter, this is referred to as a Y-Y′ plan view.) taken along line Y-Y′ of the cross-sectional view are illustrated on the left side of FIG. 18.

The pixel 21 of the first structure example is configured by stacking two substrates of a first-layer pixel substrate 401 and a second-layer pixel substrate 402. A dashed-dotted line in FIG. 18 indicates a joint surface between the first-layer pixel substrate 401 and the second-layer pixel substrate 402.

The first-layer pixel substrate 401 is formed by stacking a semiconductor substrate 421 and a wiring layer 422. The second-layer pixel substrate 402 is formed by stacking a semiconductor substrate 431 and a wiring layer 432.

As for the first-layer pixel substrate 401, in the cross-sectional view, the upper surface of the semiconductor substrate 421 on which the wiring layer 422 is formed is the front surface of the semiconductor substrate 421, and the surface opposite to the surface on which the wiring layer 422 is formed (the lower surface in FIG. 18) is the back surface of the semiconductor substrate 421, and is the light incident surface on which light is incident. On the back surface of the semiconductor substrate 421, a color filter layer, an on-chip lens, or the like can be formed as necessary.

As for the second-layer pixel substrate 402, in the cross-sectional view, the upper surface of the semiconductor substrate 431 on which the wiring layer 432 is formed is the front surface of the semiconductor substrate 431, and the surface bonded to the first-layer pixel substrate 51 is the back surface of the semiconductor substrate 431. Therefore, the first-layer pixel substrate 401 and the second-layer pixel substrate 402 are bonded together in a so-called face-to-back manner in which the front surface side of the semiconductor substrate 421 and the back surface side of the semiconductor substrate 431 are bonded together.

The semiconductor substrate 421 is a substrate using, for example, silicon (Si) as a semiconductor material. In the semiconductor substrate 421, an N-type semiconductor region 442 that is a semiconductor region of a second conductivity type different from the P-type is formed in a P-type semiconductor region (P-well layer) 441 that is a semiconductor region of a first conductivity type, whereby a photodiode PD using a PN junction is formed in a pixel unit.

As illustrated in the cross-sectional view and the Y-Y′ plan view, a pixel isolation portion 443 for electrical isolation from the adjacent pixel is formed in the outer circumferential portion of the pixel 21 in the vicinity of the boundary with the adjacent pixel of the semiconductor substrate 421. The pixel isolation portion 443 is made of, for example, an insulating film such as silicon oxide (SiO2) or a metal material such as copper (Cu), tungsten (W), or aluminum (Al).

An N-type diffusion layer 444 as a high-concentration N-type impurity region and a P-type diffusion layer 445 as a high-concentration P-type impurity region are formed at an interface with the wiring layer 422 as a front surface of the semiconductor substrate 421. Furthermore, the transfer transistor TRG is also formed. The transfer transistor TRG includes a vertical gate electrode 446. The vertical gate electrode 446 is formed by digging to a depth reaching the N-type semiconductor region 442 formed in the deep portion of the semiconductor substrate 421.

The N-type diffusion layer 444 functions as a part of the floating diffusion region FD, and the charge generated by the photodiode PD and transferred by the transfer transistor TRG is read out to the second-layer pixel substrate 402 via the N-type diffusion layer 444.

The P-type diffusion layer 445 is a well contact that supplies a fixed potential (for example, a ground or negative bias) to the P-type semiconductor region (P-well layer) 441 via a contact electrode 447.

The wiring layer 422 includes one or more layers of wiring and an interlayer insulating film 451 in addition to the vertical gate electrode 446 and the contact electrode 447 of the transfer transistor TRG. The interlayer insulating film 451 is formed of, for example, a silicon oxide film (SiO2) or the like. In FIG. 18, one or more layers of wiring are omitted for the sake of space.

The semiconductor substrate 431 of the second-layer pixel substrate 402 is a substrate including, for example, a P-type semiconductor region using, for example, silicon (Si) as a semiconductor material. As illustrated in the X-X′ plan view, the reset transistor RST, the amplification transistor AMP, and the selection transistor SEL are formed on the surface on the wiring layer 432 side, which is the front surface of the semiconductor substrate 431. The periphery of each of the reset transistor RST, the amplification transistor AMP, and the selection transistor SEL is separated by a shallow trench isolation (STI) 471.

In a predetermined depth of the semiconductor substrate 431, for example, a light shielding film 481 formed using a metal material such as copper (Cu), tungsten (W), or aluminum (Al) is embedded. The light shielding film 481 is formed in a planar region at a position covering a charge holding unit such as a metal-insulator-metal (MIM) capacitive element or an element including a pixel transistor such as the amplification transistor AMP, which is formed on the front surface side of the semiconductor substrate 431. The light shielding film 481 blocks light that has passed through the semiconductor substrate 421 of the first-layer pixel substrate 401 and entered the semiconductor substrate 431. An insulating film 482 is disposed above and below the light shielding film 481. The insulating film 482 includes, for example, a single-layer or multi-layer oxide film using silicon oxide, hafnium oxide, zircon oxide, aluminum oxide, titanium oxide, tantalum oxide, or the like.

A vertical trench 483 is formed in a region that does not interfere with the element formed on the front surface side of the semiconductor substrate 431, and an embedded metal portion 484 and an insulating film 485 in the vertical trench 483 are connected to the light shielding film 481 and the insulating film 482 in the semiconductor substrate 431, respectively.

The light shielding film 481 in the semiconductor substrate 431 is connected to a wiring 491A via the embedded metal portion 484 embedded in the vertical trench 483 and the contact wiring 493 above the embedded metal portion, and a predetermined voltage is applied from the wiring 491A to the light shielding film 481.

The vertical trench 483 is formed linearly as illustrated in the X-X′ plan view, and the inside excluding the embedded metal portion 484 connected to the contact wiring 493 is buried with the insulating film 485.

The wiring layer 432 of the second-layer pixel substrate 402 includes a plurality of layers of wirings 491 and an interlayer insulating film 492. In the example of FIG. 18, the wiring layer 432 includes four layers of the wiring 491 including the wirings 491A to 491D and the interlayer insulating film 492, but the number of layers of the wiring 491 is not limited to four.

A wiring 491A′ formed in a predetermined region of the lowermost layer in the wiring layer 432 is connected to the N-type diffusion layer 444 of the semiconductor substrate 421 of the first-layer pixel substrate 401 via the through via 501, and is connected to an N-type diffusion layer 486 of the semiconductor substrate 431 of the second-layer pixel substrate 402 via the contact wiring 502. The N-type diffusion layer 444 and the N-type diffusion layer 486 electrically connected via the wiring 491A′ constitute the floating diffusion region FD.

As described above, solid-state imaging device 1 is configured by stacking first-layer pixel substrate 401 and second-layer pixel substrate 402. In the first-layer pixel substrate 401, at least a photodiode PD and a transfer transistor TRG provided for each pixel are formed. In the second-layer pixel substrate 402, other pixel transistors Tr not formed in the first-layer pixel substrate 401, specifically, the reset transistor RST, the amplification transistor AMP, and the selection transistor SEL are formed.

In the first structure example of the pixel 21 of the second embodiment, the light shielding film 481 is arranged in the semiconductor substrate 431 of the second-layer pixel substrate 402. The light shielding film 481 blocks light incident from the back surface (the lower surface in FIG. 18) of the semiconductor substrate 421 as a light incident surface and incident on the semiconductor substrate 431 of the second-layer pixel substrate 402. As a result, it is possible to block the incidence of light on the element formed on the front surface side of the semiconductor substrate 431, particularly the N-type diffusion layer 486 as the floating diffusion region FD, and the charge holding unit such as the MIM capacitive element, and it is possible to suppress the parasitic light reception sensitivity (PLS). Furthermore, since the light shielding film 481 is formed using a metal material, noise such as surge, heat, and electromagnetism can also be blocked, so that the operation of the element can be stabilized.

For example, in a structure in which a shield layer is formed between a semiconductor substrate of a first-layer pixel substrate and a semiconductor substrate of a second-layer pixel substrate bonded together in a face-to-back manner by a solid layout on substantially the entire surface using a metal material as in the structure described in Patent Document 1 of the background art, the shield layer easily has wiring and parasitic capacitance in the wiring layer of the first-layer pixel substrate. In a case where the wiring in which the parasitic capacitance is generated is, for example, the control wiring of the transfer transistor TRG, the read speed is reduced due to the parasitic capacitance. Furthermore, for example, in a case where the wiring in which the parasitic capacitance is generated is the connection wiring of the floating diffusion region FD, the photoelectric conversion efficiency decreases due to the parasitic capacitance.

In the first structure example of the pixel 21 of the second embodiment, since the light shielding film 481 is arranged inside the semiconductor substrate 431 of the second-layer pixel substrate 402, the wiring layer 422 of the first-layer pixel substrate 401 can be freely designed without worrying about parasitic capacitance with the wiring layer 422 of the first-layer pixel substrate 401.

### <5.2 Manufacturing Method of First Structure Example of Pixel>

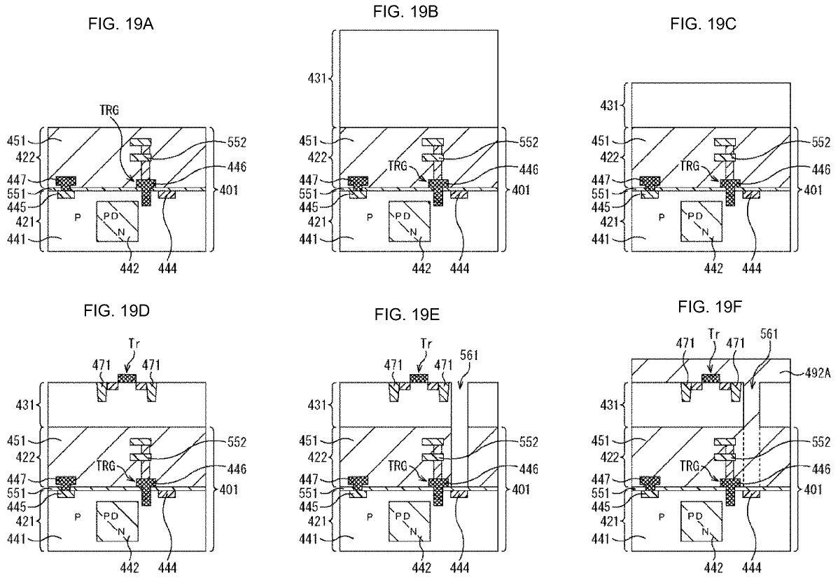

Next, a method of manufacturing the pixel 21 of the first structure example illustrated in FIG. 18 will be described with reference to FIGS. 19 to 22.

First, the first-layer pixel substrate 401 illustrated in A of FIG. 19 is manufactured. Specifically, after the photodiode PD is formed by forming the N-type semiconductor region 442 on the semiconductor substrate 421 formed of the P-type semiconductor region 441, the transfer transistor TRG, the N-type diffusion layer 444, the P-type diffusion layer 445, and the like are formed. An insulating film 551, which is not illustrated in FIG. 18, is formed on the front surface of the semiconductor substrate 421. On the upper surface of the insulating film 551, the wiring layer 422 including one or more layers of wiring 552 and an interlayer insulating film 451 is formed. The interlayer insulating film 451 is formed of, for example, a silicon oxide film (SiO2) or the like.

Next, as illustrated in B of FIG. 19, the semiconductor substrate 431 of the second-layer pixel substrate 402 is bonded to the upper surface of the wiring layer 422 of the first-layer pixel substrate 401 by, for example, plasma bonding. Then, as illustrated in C of FIG. 19, the semiconductor substrate 431 is thinned to a predetermined thickness.

Next, as illustrated in D of FIG. 19, pixel transistors Tr such as the reset transistor RST, the amplification transistor AMP, and the selection transistor SEL are formed on the upper surface (front surface) of the thinned semiconductor substrate 431. An STI 471 is formed around each pixel transistor Tr, and each pixel transistor Tr is separated.

Next, as illustrated in E of FIG. 19, the through-hole 561 is formed at a formation position of the through-via 501 which penetrates the semiconductor substrate 431 and is electrically connected to the first-layer pixel substrate 401 by dry etching or the like.

Next, as illustrated in F of FIG. 19, the insulating film 492A is embedded in the through hole 561 by using, for example, a CVD method, and the insulating film 492A is also formed with a predetermined thickness on the upper side of the semiconductor substrate 431. The insulating film 492A on the semiconductor substrate 431 is, for example, a SiO2 film, and corresponds to a part of the interlayer insulating film 492 constituting the wiring layer 432. The insulating film 492A on the semiconductor substrate 431 is planarized by chemical mechanical polishing (CMP).

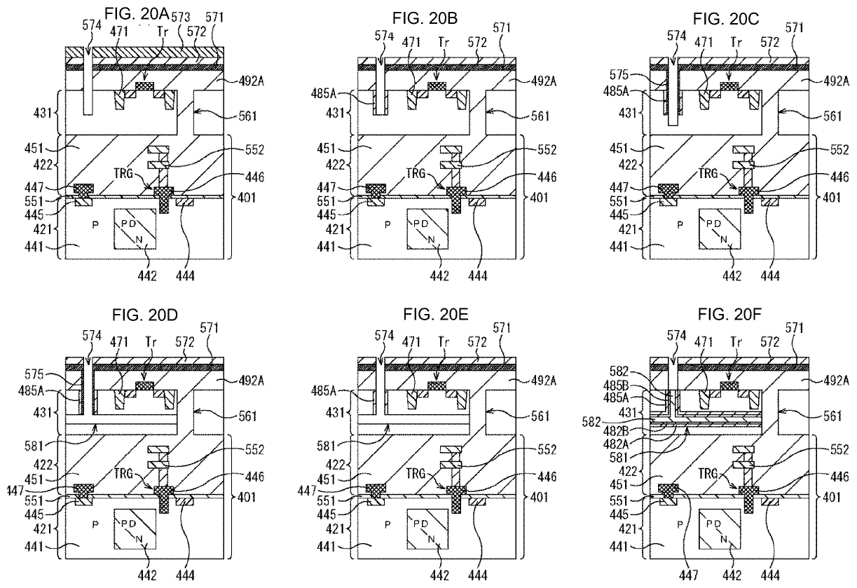

Next, as illustrated in A of FIG. 20, a silicon nitride film (SiN) 571 and a silicon oxide film (SiO2) 572 are laminated on the entire upper surface of the planarized insulating film 492A, and then the resist 573 is patterned so as to open the formation positions of the vertical trenches 483. Then, by performing dry etching using the patterned resist 573 as a mask, the vertical trenches 574 are formed up to a predetermined depth of the semiconductor substrate 431.

Next, as illustrated in B of FIG. 20, after the resist 573 is peeled off, the oxide film 485A is formed on the side wall of the vertical trench 574 in the semiconductor substrate 431 by a thermal oxidation method or the like.

Next, as illustrated in C of FIG. 20, a sidewall 575 is formed on the sidewall of the vertical trench 574, and dry etching is performed using the sidewall 575 as a mask, so that the bottom surface of the vertical trench 574 is further dug to a predetermined depth. The sidewall 575 is formed of, for example, a silicon nitride film (SiN).

Next, as illustrated in D of FIG. 20, sidewalls of portions deeper than the sidewalls 575 of the vertical trenches 574 are etched in a direction parallel to the planar direction of the semiconductor substrate 431, that is, in the lateral direction, thereby forming the lateral trenches 581. This etching in the lateral direction can be performed by, for example, crystal anisotropic etching (wet etching) in which an alkaline aqueous solution is injected into the vertical trench 574 and an etching rate is different depending on the crystal plane orientation of the semiconductor substrate 431. For example, the lateral trenches 581 can be formed by using a silicon (111) substrate as the semiconductor substrate 431 and performing crystal anisotropic etching in which the etching rate in the plane orientation (110) is sufficiently higher than the plane orientation (111). As the alkali aqueous solution, KOH, NaOH, CsOH, or the like can be applied in the case of an inorganic solution, and EDP (ethylenediamine pyrocatechol aqueous solution), N2H4 (hydrazine), NH4OH (ammonium hydroxide), TMAH (tetramethylammonium hydroxide), or the like can be applied in the case of an organic solution. The etching in the lateral direction is stopped by the insulating film 492A in the through hole 561 serving as a stopper. The similarity applies to the left end of the lateral trench 581 (not illustrated).

Next, as illustrated in E of FIG. 20, the sidewalls 575 of the vertical trenches 574 are removed by wet etching or the like.

Next, as illustrated in F of FIG. 20, after the insulating film 482 is formed on the inner circumferential surface (side surface) of the lateral trench 581 and the insulating film 485 is formed on the inner circumferential surface (side surface) of the vertical trench 574, polysilicon 582 is embedded in a cavity portion inside the insulating films.

In the example of F of FIG. 20, the insulating film 482 on the inner circumferential surface of the lateral trench 581 includes, for example, two layers of an oxide film 482A using an ISSG oxidation method and an oxide film 482B using an atomic layer deposition (ALD) method. The oxide film 482A is, for example, a silicon oxide film (SiO2), and the oxide film 482B is, for example, a hafnium oxide film (HfO2). As the configuration of the insulating film 482, other oxide films and film forming methods may be used, or a single-layer film may be used. The insulating film 485 also includes two layers of oxide films 485A and 485B, the oxide film 485A is, for example, a silicon oxide film, and the oxide film 485B is, for example, a hafnium oxide film.

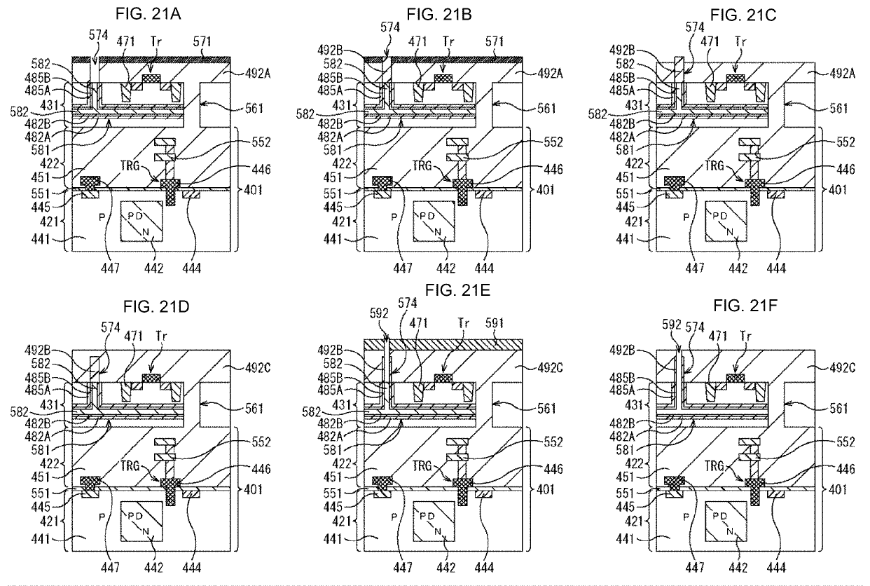

Next, as illustrated in A of FIG. 21, the silicon oxide film 572 formed on the upper surface of the insulating film 492A is removed by CMP, and the upper surface of the silicon nitride film 571 is planarized.

Next, as illustrated in B of FIG. 21, the insulating film 492B is embedded in the cavity of the vertical trench 574 above the semiconductor substrate 431. The insulating film 492B is, for example, a high density plasma (HDP) oxide film.

Next, as illustrated in C of FIG. 21, the silicon nitride film 571 on the insulating film 492A is removed by wet etching or the like, and then, as illustrated in D of FIG. 21, the insulating film is stacked up to a thickness exceeding the thickness of the insulating film 492B embedded in the vertical trench 574, thereby forming the insulating film 492C.

Next, as illustrated in E of FIG. 21, a resist 591 is applied to the upper surface of the insulating film 492C, and patterning is performed so that formation positions of the vertical trenches 574 are opened. Then, using the patterned resist 591 as a mask, etching is performed to a depth at which the polysilicon 582 in the vertical trench 574 is exposed to form the through-hole 592.

Next, as illustrated in F of FIG. 21, the polysilicon 582 in the vertical trench 574 and the lateral trench 581 is removed.

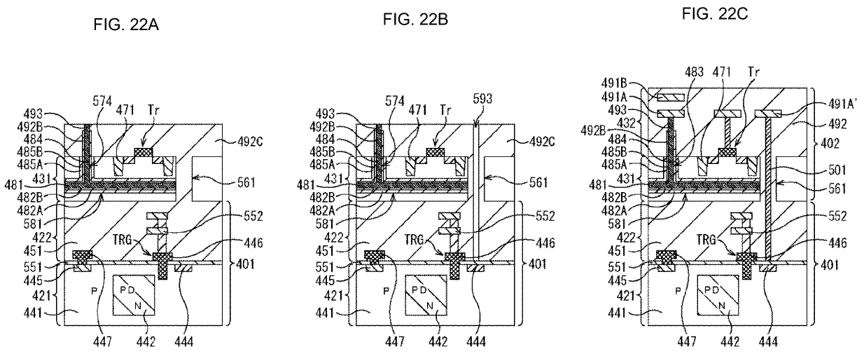

Next, as illustrated in A of FIG. 22, a metal material such as copper (Cu), tungsten (W), or aluminum (Al) is embedded in the cavities in the vertical trench 574 and the lateral trench 581 after the polysilicon 582 is removed. In the present embodiment, for example, tungsten is embedded in the vertical trench 574 and the lateral trench 581. By embedding the metal material, the light shielding film 481 is formed in the lateral trench 581 in the semiconductor substrate 431, and the embedded metal portion 484 is formed in the vertical trench 574. A portion of the vertical trench 574 in the semiconductor substrate 431 corresponds to the vertical trench 483 in FIG. 18. The metal material in the insulating film 492C above the semiconductor substrate 431 is the contact wiring 493.

Next, as illustrated in B of FIG. 22, a resist (not illustrated) is patterned so as to open the formation position of the through-via 501, and then dry etching is performed to form the through-hole 593 up to the N-type diffusion layer 444 of the semiconductor substrate 421 of the first-layer pixel substrate 401.

Next, as illustrated in C of FIG. 22, a metal material such as tungsten (W) is embedded in the through-hole 593 to form the through-via 501. Moreover, by further forming the wirings 491A to 491D and the interlayer insulating film 492 on the insulating film 492C by a dual damascene method or the like, the wiring layer 432 is completed, and the second-layer pixel substrate 402 is completed.

As described above, the pixel 21 in FIG. 18 formed by stacking the two substrates of the first-layer pixel substrate 401 and the second-layer pixel substrate 402 is completed.

According to the method of manufacturing the pixel 21 of the first structure example of the second embodiment described above, the light shielding film 481 is formed after the semiconductor substrate 431 of the second-layer pixel substrate 402 is bonded to the first-layer pixel substrate 401, and the pixel transistors Tr such as the amplification transistors AMP and the selection transistors SEL are formed on the semiconductor substrate 431. As a result, it is possible to prevent positional deviation between an element to be shielded from light and the light shielding film 481.

Conversely, when the semiconductor substrate 431 on which the element such as the pixel transistor Tr is formed is bonded after the light shielding film 481 is formed, the positional deviation between the element to be shielded from light and the light shielding film 481 occurs due to the bonding deviation, and the light shielding property may be weakened. According to the above-described manufacturing method, it is possible to prevent such positional deviation and avoid deterioration of light shielding performance.

### <5.3 Second Structure Example of Pixel According to Second Embodiment>

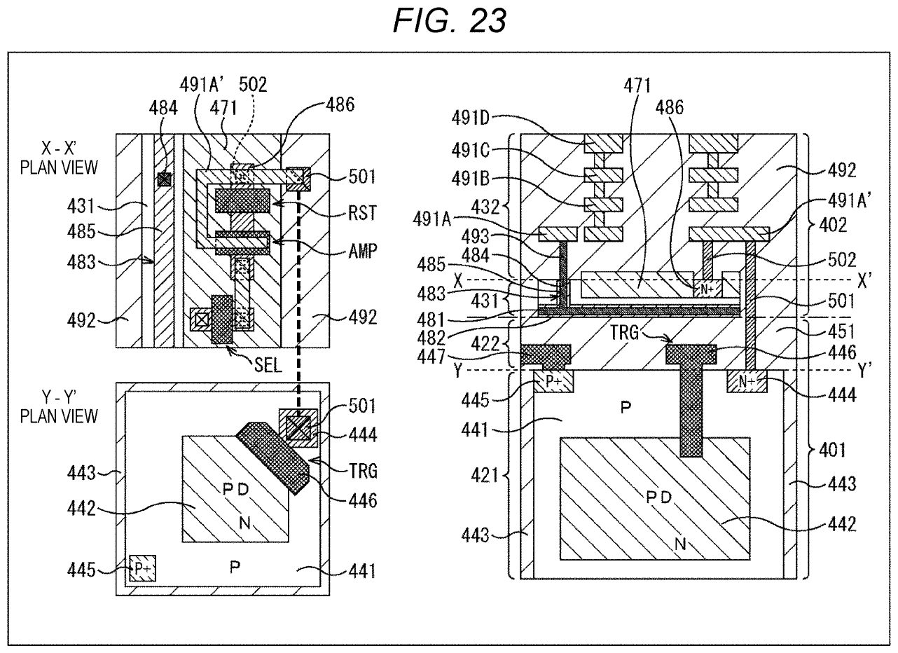

FIG. 23 is a cross-sectional view schematically illustrating a second structure example of the pixel 21 in the second embodiment.

In FIG. 23, parts corresponding to those in the first structure example illustrated in FIG. 18 are denoted by the same reference numerals, and description of the parts will be omitted as appropriate, and description will be given focusing on different parts. The similarity applies to the third and subsequent structural examples described below.

In the first structure example illustrated in FIG. 18, a layer including the light shielding film 481 of the second-layer pixel substrate 402 and the insulating films 482 above and below the light shielding film is formed to be embedded in the semiconductor substrate 431. In other words, the layers including the light shielding film 481 and the insulating films 482 on the upper and lower sides thereof are arranged such that both the upper and lower surfaces thereof are in contact with the same semiconductor substrate 431.

On the other hand, in the second structural example of FIG. 23, a layer including the light shielding film 481 and the insulating films 482 on the upper and lower sides thereof is formed at the bottom of the semiconductor substrate 431. In other words, the layers including the light shielding film 481 and the upper and lower insulating films 482 are arranged such that the upper side thereof is in contact with the semiconductor substrate 431 and the lower side thereof is in contact with the interlayer insulating film 451 of the wiring layer 422 of the first-layer pixel substrate 401.

In a case where the light shielding film 481 is disposed at the bottom of the semiconductor substrate 431, the thickness of the semiconductor substrate 431 can be reduced. As a result, since the thickness of the entire second-layer pixel substrate 402 can be reduced, the length (depth) of the through-via 501 that penetrates the semiconductor substrate 431 and is electrically connected to the first-layer pixel substrate 401 can be shortened.

Other structures of the second structure example are similar to those of the first structure example described above.

According to the second structure example of FIG. 23, similarly to the first structure example, the parasitic light reception sensitivity can be suppressed by the light shielding film 481 arranged at the bottom of the semiconductor substrate 431 of the second-layer pixel substrate 402. Furthermore, since the light shielding film 481 is formed using a metal material, noise such as surge, heat, and electromagnetism can also be blocked, so that the operation of the element can be stabilized.

Furthermore, by disposing the light shielding film 481 at the bottom of the semiconductor substrate 431 of the second-layer pixel substrate 402, the thickness of the semiconductor substrate 431 can be reduced, and the length (depth) of the through via 501 is shortened, so that the photoelectric conversion efficiency can be improved.

### <5.4 Third Structure Example of Pixel According to Second Embodiment>

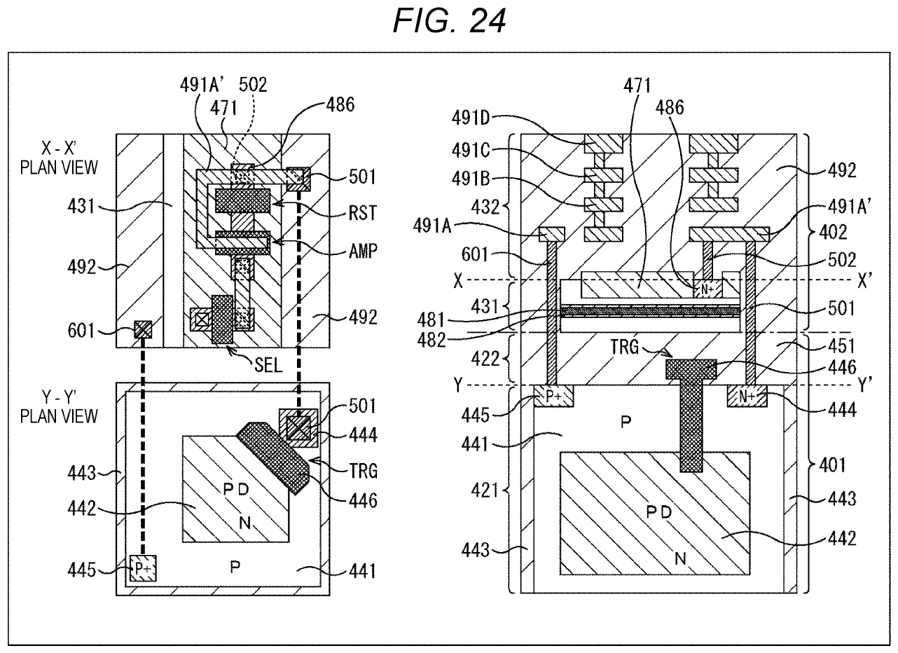

FIG. 24 is a cross-sectional view schematically illustrating a third structure example of the pixel 21 according to the second embodiment.

In FIG. 24, parts corresponding to those in the first structure example illustrated in FIG. 18 are denoted by the same reference numerals, and description of the parts will be omitted as appropriate, and description will be given focusing on different parts.

In the first structure example illustrated in FIG. 18, the vertical trench 483 is formed from the front surface side of the semiconductor substrate 431 of the second-layer pixel substrate 402, and the embedded metal portion 484 and the insulating film 485 in the vertical trench 483 are connected to the light shielding film 481 and the insulating film 482 formed inside the semiconductor substrate 431. As described in the manufacturing method of the first structure example, the vertical trench 483 is used for etching in the lateral direction for forming the lateral trench 581 in which the light shielding film 481 is embedded.

On the other hand, in the third structure example of FIG. 24, the vertical trench 483, and the metal portion 484 and the insulating film 485 embedded therein are omitted. The wiring 491A located at the lowermost layer of the wiring layer 432 is connected to the P-type diffusion layer 445 which is a well contact via the through via 601.

Although the manufacturing method of the third structural example will be described later, the cavity in which the layer including the light shielding film 481 and the upper and lower insulating films 482 is embedded is formed by etching in the lateral direction using the through-hole opened to form the through-via 501.

Other structures of the third structure example are similar to those of the first structure example described above.

According to the third structure example of FIG. 24, similarly to the first structure example, the parasitic light reception sensitivity can be suppressed by the light shielding film 481 arranged in the semiconductor substrate 431 of the second-layer pixel substrate 402. Furthermore, since the light shielding film 481 is formed using a metal material, noise such as surge, heat, and electromagnetism can also be blocked, so that the operation of the element can be stabilized.

Furthermore, since the light shielding film 481 is disposed inside the semiconductor substrate 431 of the second-layer pixel substrate 402, there is no need to worry about parasitic capacitance with the wiring layer 422 of the first-layer pixel substrate 401. As a result, the wiring layer 422 of the first-layer pixel substrate 401 can be freely designed.

### <5.5 Manufacturing Method of Third Structure Example of Pixel>

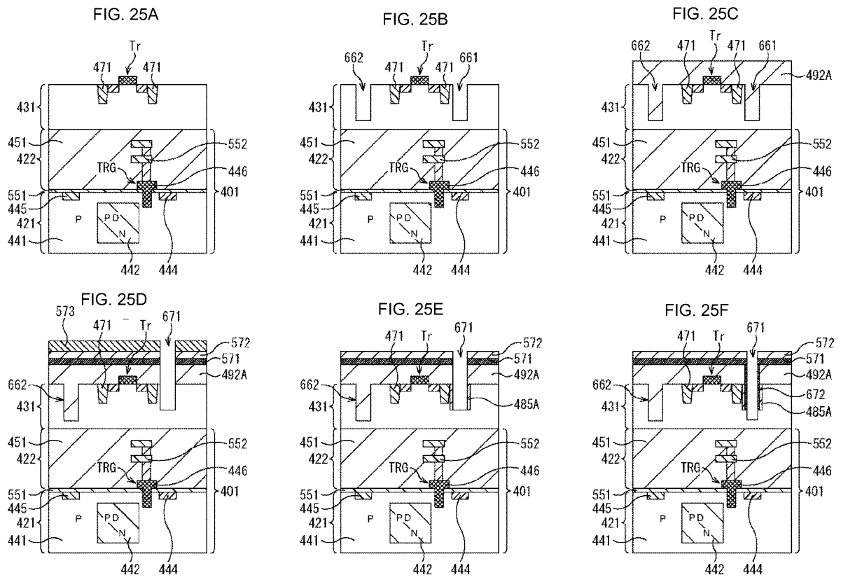

Next, a method of manufacturing the pixel 21 of the third structure example illustrated in FIG. 24 will be described with reference to FIGS. 25 to 28.

The manufacturing method up to the state illustrated in A of FIG. 25, that is, the state in which the pixel transistor Tr such as the amplification transistor AMP is formed on the upper surface of the semiconductor substrate 431 bonded on the first-layer pixel substrate 401 is similar to that in the first structure example. Specifically, after the first-layer pixel substrate 401 is formed by each step described with reference to A to D of FIG. 19, the pixel transistor Tr is formed on the semiconductor substrate 431 bonded to the first-layer pixel substrate 401. In A of FIG. 19 of the first structure example, the contact electrode 447 is formed on the P-type diffusion layer 445, but in A of FIG. 25, the contact electrode 447 is not formed.

Next, as illustrated in B of FIG. 25, trenches 661 and 662 are formed at formation positions of the through vias 501 and 601, respectively. The trenches 661 and 662 are formed at a predetermined depth not penetrating the semiconductor substrate 431 by, for example, dry etching.

Next, as illustrated in C of FIG. 25, the insulating film 492A is embedded inside the trenches 661 and 662 by using, for example, a CVD method, and the insulating film 492A is also formed with a predetermined thickness on the upper side of the semiconductor substrate 431. The insulating film 492A on the semiconductor substrate 431 is, for example, a SiO2 film, and corresponds to a part of the interlayer insulating film 492 constituting the wiring layer 432. The insulating film 492A on the semiconductor substrate 431 is planarized by CMP.

Next, as illustrated in D of FIG. 25, after the silicon nitride film 571 and the silicon oxide film 572 are laminated on the entire upper surface of the planarized insulating film 492A, the resist 573 is patterned so as to open the formation position of the through-via 501. Then, using the patterned resist 573 as a mask, the semiconductor substrate 431 is dug to a predetermined depth by dry etching, and the vertical trench 671 is formed.

Next, as illustrated in E of FIG. 25, after the resist 573 is peeled off, the oxide film 485A is formed on the side wall of the vertical trench 671 in the semiconductor substrate 431 by a thermal oxidation method or the like.

Next, as illustrated in F of FIG. 25, a sidewall 672 is formed on the sidewall of the vertical trench 671, and dry etching is performed using the sidewall 672 as a mask, so that the bottom surface of the vertical trench 671 is further dug to a predetermined depth. The sidewall 672 is formed of, for example, a silicon nitride film (SiN).

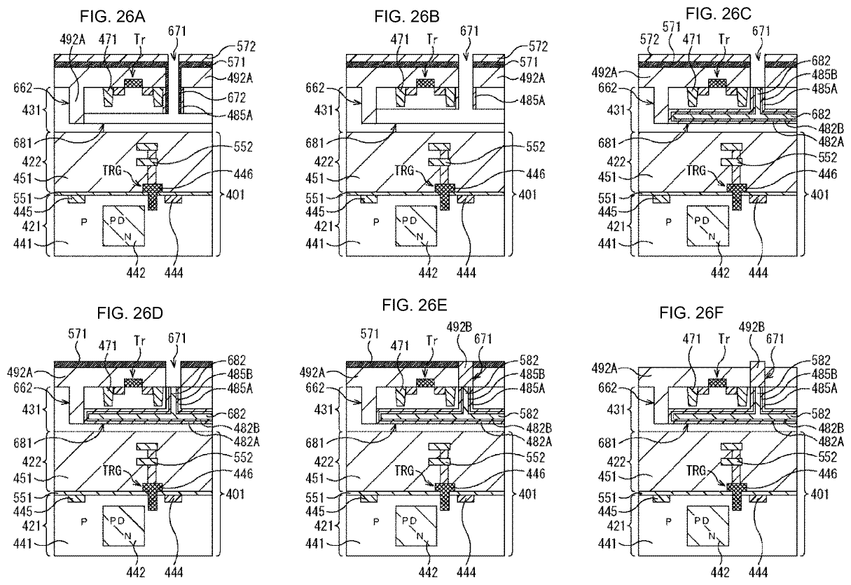

Next, as illustrated in A of FIG. 26, sidewalls of portions deeper than the sidewalls 672 of the vertical trenches 671 are etched in a direction parallel to the planar direction of the semiconductor substrate 431, that is, in the lateral direction, thereby forming the lateral trenches 681. This etching in the lateral direction can be performed by crystal anisotropic etching using a property that the etching rate varies depending on the crystal plane orientation, similarly to the manufacturing method of the first structure example. The etching in the lateral direction is stopped by the insulating film 492A in the trench 662 serving as a stopper. The similarity applies to the right end of the lateral trench 681 (not illustrated).

Next, as illustrated in B of FIG. 26, the sidewalls 672 of the vertical trenches 671 are removed by wet etching or the like.

Next, as illustrated in C of FIG. 26, after the insulating film 482 is formed on the inner circumferential surface (side surface) of the lateral trench 681 and the insulating film 485 is formed on the inner circumferential surface (side surface) of the vertical trench 671, polysilicon 682 is embedded in a cavity portion inside the insulating films.

In the example of C of FIG. 26, the insulating film 482 on the inner circumferential surface of the lateral trench 681 includes, for example, two layers of an oxide film 482A using the ISSG oxidation method and an oxide film 482B using the atomic layer deposition method. The oxide film 482A is, for example, a silicon oxide film, and the oxide film 482B is, for example, a hafnium oxide film. As the configuration of the insulating film 482, other oxide films and film forming methods may be used, or a single-layer film may be used. The insulating film 485 also includes two layers of oxide films 485A and 485B, the oxide film 485A is, for example, a silicon oxide film, and the oxide film 485B is, for example, a hafnium oxide film.

Next, as illustrated in D of FIG. 26, the silicon oxide film 572 formed on the upper surface of the insulating film 492A is removed by CMP, and the upper surface of the silicon nitride film 571 is planarized.

Next, as illustrated in E of FIG. 26, the insulating film 492B is embedded in the cavity of the vertical trench 671 above the semiconductor substrate 431. The insulating film 492B is, for example, an HDP oxide film.

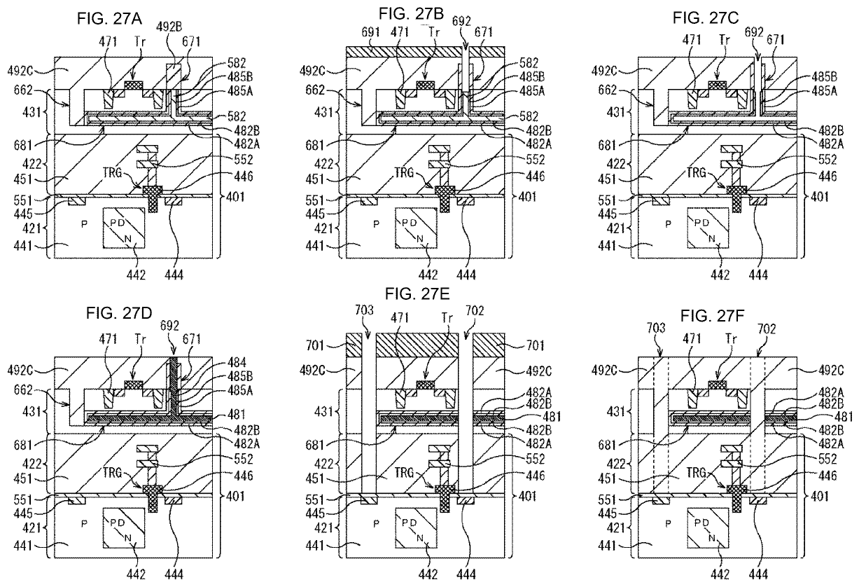

Next, as illustrated in F of FIG. 26, the silicon nitride film 571 on the insulating film 492A is removed by wet etching or the like, and then, as illustrated in A of FIG. 27, the insulating film is stacked up to a thickness exceeding the thickness of the insulating film 492B embedded in the vertical trench 671, thereby forming the insulating film 492C.

Next, as illustrated in B of FIG. 27, a resist 691 is applied to the upper surface of the insulating film 492C, and patterning is performed so that formation positions of the vertical trenches 671 are opened. Then, using the patterned resist 691 as a mask, etching is performed to a depth at which the polysilicon 582 in the vertical trench 671 is exposed to form the through-hole 692.

Next, as illustrated in C of FIG. 27, the polysilicon 582 in the vertical trench 671 and the lateral trench 681 is removed.

Next, as illustrated in D of FIG. 27, a metal material such as copper, tungsten, or aluminum is embedded in the cavity after the polysilicon 582 is removed. In the present embodiment, for example, tungsten is embedded in the cavities in the vertical trench 671 and the lateral trench 681. By embedding the metal material, the light shielding film 481 is formed in the lateral trench 681 in the semiconductor substrate 431, and the embedded metal portion 484 is formed in the vertical trench 671.

Next, as illustrated in E of FIG. 27, a resist 701 is applied onto the insulating film 492C, and patterning is performed so that formation positions of the through-vias 501 and 601 are opened. Then, by performing dry etching using the patterned resist 701 as a mask, the through-holes 702 and 703 penetrating to the wiring layer 422 of the first-layer pixel substrate 401 are formed. By forming the through-hole 702, the embedded metal portion 484 and the insulating film 485 of the vertical trench 671 are removed.

Next, as illustrated in F of FIG. 27, an insulating film is embedded in each of the through holes 702 and 703 by using, for example, a CVD method, and the upper surface of the insulating film 492C is planarized by CMP.

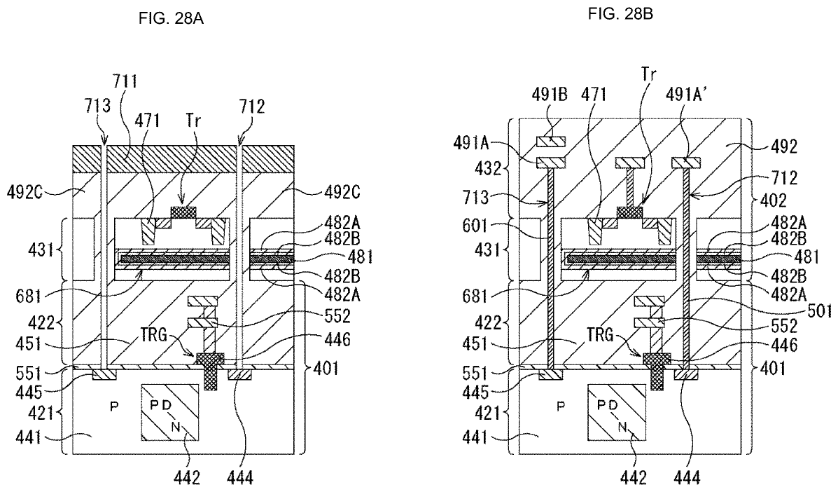

Next, as illustrated in A of FIG. 28, a resist 711 is applied onto the insulating film 492C, and patterning is performed so that formation positions of the through-vias 501 and 601 are opened. Then, by performing dry etching using the patterned resist 711 as a mask, the through-holes 712 and 713 are formed until the N-type diffusion layer 444 and the P-type diffusion layer 445 of the semiconductor substrate 421 of the first-layer pixel substrate 401 are exposed.

Next, as illustrated in B of FIG. 28, through vias 501 and 601 are formed by embedding a metal material such as tungsten in the through holes 712 and 713, for example. Moreover, by further forming the wirings 491A to 491D and the interlayer insulating film 492 on the insulating film 492C, the wiring layer 432 is completed, and the second-layer pixel substrate 402 is completed.

As described above, the pixel 21 in FIG. 24 formed by stacking the two substrates of the first-layer pixel substrate 401 and the second-layer pixel substrate 402 is completed.

According to the method of manufacturing the pixel 21 of the third structure example of the second embodiment, the light shielding film 481 is formed after the semiconductor substrate 431 of the second-layer pixel substrate 402 is bonded to the first-layer pixel substrate 401 and the pixel transistors Tr such as the amplification transistors AMP and the selection transistors SEL are formed on the semiconductor substrate 431. As a result, it is possible to prevent positional deviation between an element to be shielded from light and the light shielding film 481.

According to the method of manufacturing the pixel 21 of the third structure example, it is possible to form the light shielding film 481 by forming the lateral trench 681 using the through-hole for forming the through-via 501 without providing the vertical trench for forming the lateral trench 681 in which the light shielding film 481 is embedded.

### <5.6 Fourth Structure Example of Pixel According to Second Embodiment>

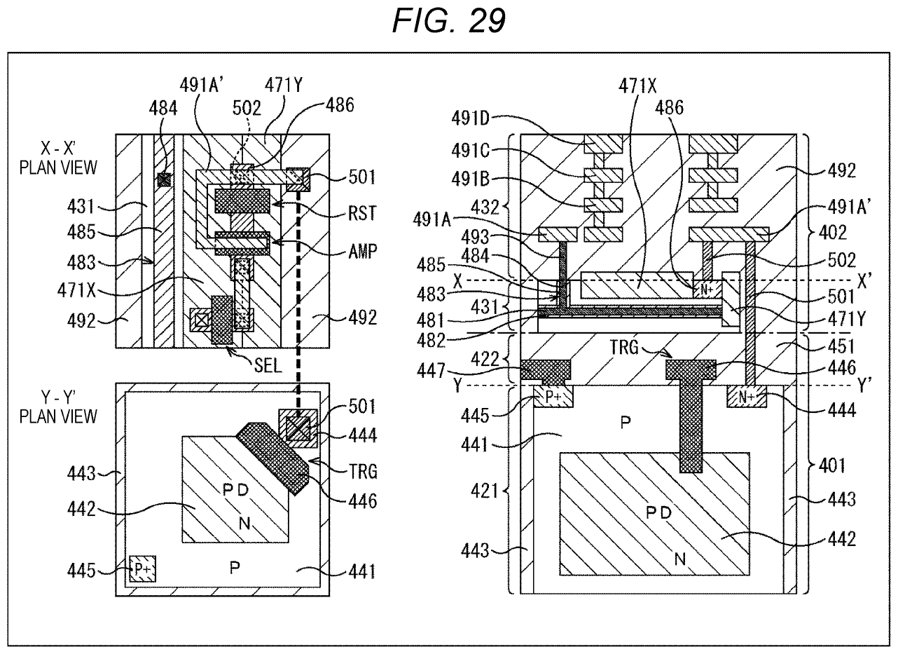

FIG. 29 is a cross-sectional view schematically illustrating a fourth structure example of the pixel 21 in the second embodiment.

In FIG. 29, parts corresponding to those in the first structure example illustrated in FIG. 18 are denoted by the same reference numerals, and description of the parts will be omitted as appropriate, and description will be given focusing on different parts.

In the first structure example illustrated in FIG. 18, the STI 471 that isolates elements such as the reset transistor RST, the amplification transistor AMP, and the selection transistor SEL is formed at the same depth (thickness) on the front surface side of the semiconductor substrate 431 of the second-layer pixel substrate 402.

On the other hand, in the fourth structure example of FIG. 29, two regions of STI 471X and STI 471Y are formed, and STI 471X and STI 471Y have different depths. STI 471Y having a deeper depth is formed up to a position deeper than a layer including the light shielding film 481 and the upper and lower insulating films 482, and a layer including the light shielding film 481 and the upper and lower insulating films 482 is in contact with a side surface of STI 471Y.

Other structures of the fourth structure example are similar to those of the first structure example described above.

According to the fourth structure example in FIG. 29, similarly to the first structure example, the parasitic light reception sensitivity can be suppressed by the light shielding film 481 arranged at the bottom of the semiconductor substrate 431 of the second-layer pixel substrate 402. Furthermore, since the light shielding film 481 is formed using a metal material, noise such as surge, heat, and electromagnetism can also be blocked, so that the operation of the element can be stabilized.

Furthermore, since the light shielding film 481 is disposed inside the semiconductor substrate 431 of the second-layer pixel substrate 402, the wiring layer 422 of the first-layer pixel substrate 401 can be freely designed without concern for parasitic capacitance with the wiring layer 422 of the first-layer pixel substrate 401.

The pixel 21 of the fourth structure example can be manufactured by a manufacturing method basically similar to that of the first structure example. In the process of D of FIG. 20 described in the manufacturing method of the first structure example, that is, the process of forming the lateral trench 581 by etching the semiconductor substrate 431 in the lateral direction, the etching is stopped by the STI 471Y. In the fourth structure example, the STI 471Y can be used as a stopper for etching for forming the lateral trench 581.

### <5.7 Fifth Structure Example of Pixel According to Second Embodiment>

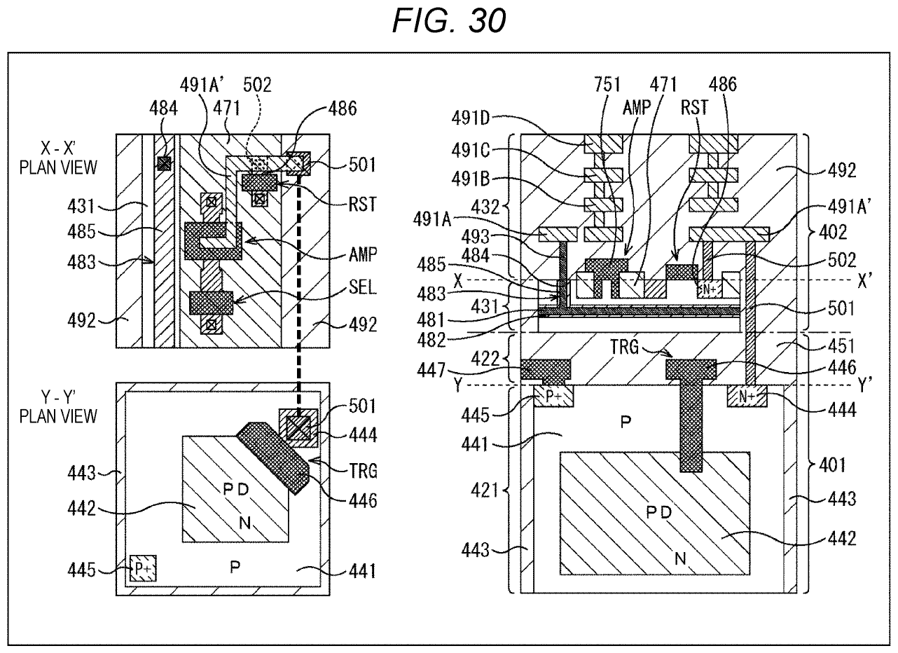

FIG. 30 is a cross-sectional view schematically illustrating a fifth structure example of the pixel 21 in the second embodiment.

In FIG. 30, parts corresponding to those in the first structure example illustrated in FIG. 18 are denoted by the same reference numerals, and description of the parts will be omitted as appropriate, and description will be given focusing on different parts.

The fifth structure example in FIG. 30 is different from the first structure example illustrated in FIG. 18 in the structure of the amplification transistor AMP formed on the front surface side of the semiconductor substrate 431 of the second-layer pixel substrate 402. Therefore, the reset transistor RST and the amplification transistor AMP are illustrated on the front surface side of the semiconductor substrate 431 in the cross-sectional view on the right side of FIG. 30.

Although the structure of the amplification transistor AMP has not been particularly mentioned in the first structure example, the amplification transistor AMP of the first structure example can be configured by, for example, a MOS transistor having a planar gate electrode.

On the other hand, the amplification transistor AMP in the fifth structure example includes a MOS transistor having a gate electrode 751 having a dug structure. As a result, as illustrated in the X-X′ plan view, the planar arrangement of the amplification transistor AMP and the selection transistor SEL is also changed from that of the first structure example.

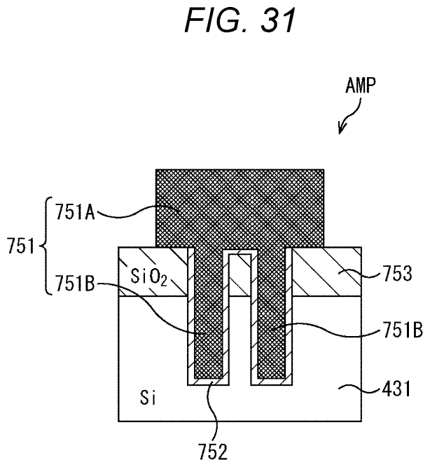

FIG. 31 is an enlarged cross-sectional view of the vicinity of the gate electrode 751 of the amplification transistor AMP in the fifth structure example.

The gate electrode 751 of the amplification transistor AMP includes a planar gate portion 751A on the upper surface of the semiconductor substrate 431 and a plurality of dug portions 751B dug in the semiconductor substrate 431. A gate insulating film 752 is formed on a side surface and a bottom surface of the dug portion 751B, and an insulating film 753 is formed between the front surface of the semiconductor substrate 431 and the planar gate portion 751A. The gate insulating film 752 and the insulating film 753 are formed of, for example, a silicon oxide film (SiO2).

The amplification transistor AMP including the gate electrode 751 having such a dug structure can increase the effective gate width W by forming a current path at a position away from the interface of the insulating film 753, and can realize low noise.

Other structures of the fifth structure example are similar to those of the first structure example described above.

According to the fifth structure example in FIGS. 30 and 31, similarly to the first structure example, the parasitic light reception sensitivity can be suppressed by the light shielding film 481 disposed in the semiconductor substrate 431 of the second-layer pixel substrate 402. Furthermore, since the light shielding film 481 is formed using a metal material, noise such as surge, heat, and electromagnetism can also be blocked, so that the operation of the element can be stabilized.

Furthermore, since the light shielding film 481 is disposed inside the semiconductor substrate 431 of the second-layer pixel substrate 402, there is no need to worry about parasitic capacitance with the wiring layer 422 of the first-layer pixel substrate 401. As a result, the wiring layer 422 of the first-layer pixel substrate 401 can be freely designed.

Moreover, the noise of the pixel signal can be further reduced by adopting the MOS transistor having the gate electrode 751 of the dug structure as the amplification transistor AMP.

### 6. Summary of Pixels According to Second Embodiment

The pixel 21 according to the second embodiment described above is configured by stacking a first-layer pixel substrate 401 (first substrate) including a semiconductor substrate 421 on which at least photodiodes PD provided in pixel units are formed and a second-layer pixel substrate 402 (second substrate) including a semiconductor substrate 431 on which active elements such as amplification transistors AMP are formed. Furthermore, the pixel 21 includes the light shielding film 481 on the semiconductor substrate 431 of the second-layer pixel substrate 402. The light shielding film 481 can suppress parasitic light reception sensitivity. Furthermore, since the light shielding film 481 is formed using a metal material, noise such as surge, heat, and electromagnetism can also be blocked, so that the operation of the element can be stabilized. The wiring layer 422 of the first-layer pixel substrate 401 can be freely designed without concern for parasitic capacitance with the wiring layer 422 of the first-layer pixel substrate 401.

### 7. Other Configuration Examples of Pixel Circuit

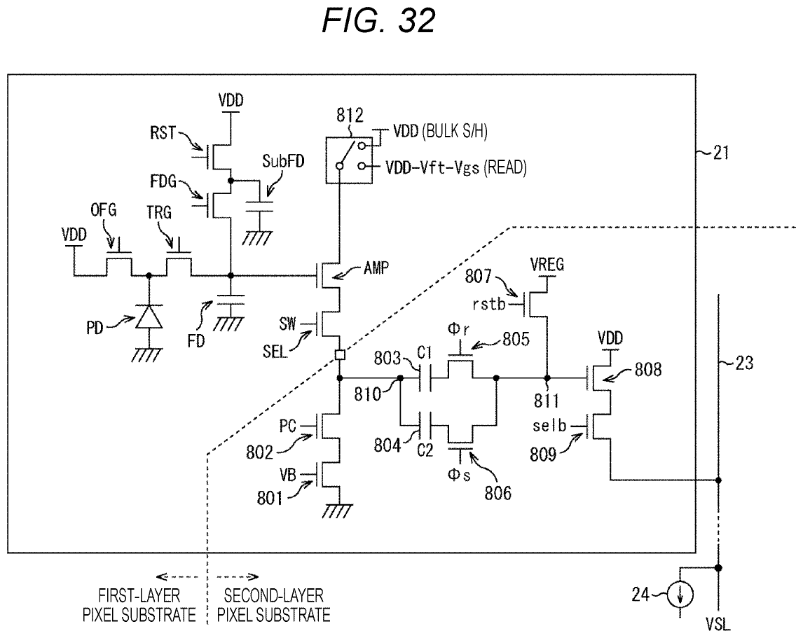

FIG. 32 illustrates another circuit configuration example that can be adopted as the pixel 21 of the pixel array unit 11.

The pixel 21 in FIG. 32 has a configuration in which two paired capacitive elements are provided for each pixel, and the pair of capacitive elements are caused to hold two signals of a reset level and a signal level to be subjected to AD conversion.

Specifically, the pixel 21 includes a photodiode PD, a transfer transistor TRG, a floating diffusion region FD, a reset transistor RST, an amplification transistor AMP, a discharge transistor OFG, and a selection transistor SEL. These elements are formed on, for example, the first-layer pixel substrate.

Furthermore, the pixel 21 includes a current source transistor 801, a current source switch transistor 802, capacitive elements 803 and 804, capacitance selection transistors 805 and 806, a post-stage reset transistor 807, a post-stage amplification transistor 808, and a post-stage selection transistor 809. These elements are formed on, for example, the second-layer pixel substrate.

Note that, for example, an N-type MOS transistor (MOS FET) can be used for various pixel transistors in the pixel 21. In this case, when the pixel transistor is turned on by the drive signal supplied to the gate, it is in a closed state in which the drain and the source are connected.

The photodiode PD is a photoelectric conversion unit provided in the pixel 21, receives light from a subject, generates a charge corresponding to the amount of received light by photoelectric conversion, and accumulates the charge. The photodiode PD has an anode terminal grounded and a cathode terminal connected to the floating diffusion region FD via the transfer transistor TRG.

The transfer transistor TRG is provided between the photodiode PD and the floating diffusion region FD, and transfers the charge accumulated in the photodiode PD to the floating diffusion region FD when turned on by a transfer drive signal supplied to the gate.

The floating diffusion region FD is a voltage conversion unit that converts the charge transferred from the photodiode PD via the transfer transistor TRG into an electric signal, for example, a voltage signal, and outputs the electric signal. The floating diffusion region FD is also connected to the source of the switching transistor FDG and the gate of the amplification transistor AMP.

The discharge transistor OFG is provided between the power supply voltage VDD and the photodiode PD, and discharges the unnecessary charge accumulated in the photodiode PD to the drain (constant voltage source VDD) when turned on by a discharge signal supplied to the gate.

When the reset transistor RST is turned on by a reset drive signal supplied to the gate, the charge accumulated in the floating diffusion region FD is discharged to the drain (constant voltage source VDD), and the potential of the floating diffusion region FD is reset. Note that when the reset transistor RST is turned on, the switching transistor FDG is also turned on at the same time, and the additional capacitance subFD is also reset.

The switching transistor FDG turns on and off the connection between the floating diffusion region FD and the additional capacitance subFD according to the capacitance switching signal supplied to the gate, and switches the conversion efficiency. Specifically, the vertical drive unit 12 turns on the switching transistor FDG and connects the floating diffusion region FD and the additional capacitance subFD, for example, when the amount of incident light is high illuminance. Therefore, it is possible to accumulate more electric charges when luminous intensity is high. On the other hand, when the amount of incident light is low illuminance, the vertical drive unit 12 turns off the switching transistor FDG and separates the additional capacitance subFD from the floating diffusion region FD. Therefore, it is possible to increase conversion efficiency.

The amplification transistor AMP outputs a signal corresponding to the potential of the floating diffusion region FD. That is, the amplification transistor AMP forms a source follower circuit with the current source transistor 801, and a signal indicating a level corresponding to the charge accumulated in the floating diffusion region FD is output from the amplification transistor AMP to the capacitance input node 810 via the selection transistor SEL. The power supply voltage VDD is supplied to the drain of the amplification transistor AMP during an exposure period in which all the pixels are simultaneously executed, and a voltage (VDD-Vft-Vgs) is supplied during a readout period in which the signals held in the pair of capacitive elements 803 and 804 are read out. The voltage Vft is a variation amount of the reset feedthrough of the reset transistor RST, and the voltage Vgs is a gate-source voltage of the amplification transistor AMP. The switch 812 for switching between the power supply voltage VDD and the voltage (VDD-Vft-Vgs) is provided, for example, in the vertical drive unit 12.

The selection transistor SEL is connected between the connection point between the drain of the current source switch transistor 802 and the capacitance input node 810 and the source of the amplification transistor AMP, and the connection selection signal SW is supplied to the gate of the selection transistor SEL. When the selection transistor SEL is turned on by the connection selection signal SW, the selection transistor SEL enters a conductive state and is connected to a subsequent stage circuit such as the capacitive elements 803 and 804. The selection transistor SEL is controlled to be turned on from immediately before the end of the exposure period to immediately before the start of reading of each pixel row, and connects the pre-stage circuit formed on the first-layer pixel substrate and the post-stage circuit formed on the second-layer pixel substrate. On the other hand, during a readout period in which signals held in the pair of capacitive elements 803 and 804 are read out, the selection transistor SEL is controlled to be turned off, and the pre-stage circuit formed on the first-layer pixel substrate is disconnected from the post-stage circuit.

The current source transistor 801 is a transistor serving as a current source constituting a source follower circuit of a preceding stage together with the amplification transistor AMP, and a predetermined bias voltage VB is supplied to a gate thereof.

The current source switch transistor 802 is a transistor for turning on and off the current source of the source follower circuit of the previous stage by the switch signal PC supplied to the gate. The current source switch transistor 802 is controlled to be turned on during the global shutter operation executed simultaneously for all the pixels, specifically, during the exposure operation and the holding operation of holding (sample and hold) the two signals of the reset level and the signal level in the pair of capacitive elements 803 and 804, and the source follower circuit in the previous stage is turned on. On the other hand, during a readout period in which signals held in the pair of capacitive elements 803 and 804 are read out, the current source switch transistor 802 is controlled to be turned off, and the source follower circuit in the previous stage is turned off.

One end of each of the capacitive elements 803 and 804 is commonly connected to the capacitance input node 810. The other end of the capacitive element 803 is connected to the capacitance selection transistor 805, and the other end of the capacitive element 804 is connected to the capacitance selection transistor 806. The capacitive elements 803 and 804 hold a predetermined voltage level output from the amplification transistor AMP. The storage capacitance of the capacitive element 803 is denoted by C1, and the storage capacitance of the capacitive element 804 is denoted by C2.

The capacitance selection transistor 805 selects the capacitive element 803 and is connected to the subsequent stage, and the capacitance selection transistor 806 selects the capacitive element 804 and is connected to the subsequent stage. More specifically, when turned on by a selection signal Or from the vertical drive unit 12, the capacitance selection transistor 805 connects the capacitive element 803 and the post-stage amplification transistor node 811. When turned on by a selection signal Φs from the vertical drive unit 12, the capacitance selection transistor 806 connects the capacitive element 804 and the post-stage amplification transistor node 811.

When turned on by the subsequent stage reset signal rstb from the vertical drive unit 12, the post-stage reset transistor 807 initializes the level of the post-stage amplification transistor node 811 to a predetermined potential VREG. A potential (for example, a potential lower than the power supply voltage VDD) different from the power supply voltage VDD is set as the potential VREG.

The post-stage amplification transistor 808 forms a source follower circuit with the constant current source 24 connected via the vertical signal line 23, amplifies the voltage level supplied to the post-stage amplification transistor node 811, and outputs the amplified voltage level to the vertical signal line 23 via the post-stage selection transistor 809. When turned on by the post-stage selection signal selb from the vertical drive unit 12, the post-stage selection transistor 809 outputs a signal of a voltage level amplified by the post-stage amplification transistor 808 to the vertical signal line 23 as the pixel signal VSL.

The operation of the pixel 21 in FIG. 32 will be briefly described.

First, all the pixels 21 of the pixel array unit 11 simultaneously perform a global shutter operation. Specifically, after the discharge transistor OFG is turned on to reset unnecessary charges of the photodiode PD, exposure is started, and charges corresponding to the amount of received light are generated and accumulated in the photodiode PD. Next, before the transfer transistor TRG is turned on and the accumulated charge of the photodiode PD is transferred, the reset transistor RST and the switching transistor FDG are turned on, and the floating diffusion region FD and the additional capacitance subFD are reset. The capacitance selection transistor 805 is turned on together with the reset of the floating diffusion region FD, and the potential of the floating diffusion region FD is read and held (sampled and held) in the capacitive element 803 as a signal of a reset level (P-phase data). Next, the transfer transistor TRG and the capacitance selection transistor 806 are turned on, the accumulated charge of the photodiode PD is transferred to the floating diffusion region FD, and the potential of the floating diffusion region FD is held (sampled and held) in the capacitive element 804 as a signal of a signal level (D-phase data).

Next, each pixel 21 is selected in units of rows of the pixel array unit 11, and signals of the reset level and the signal level held in the capacitive elements 803 and 804 of each pixel 21 are read out to the column processing unit 13 in units of rows.

In the first embodiment of the pixel 21 described above, the capacitive elements 803 and 804 are formed in the second-layer pixel substrate 52, and the dielectric multilayer film 73 suppresses light incidence on the capacitive elements 803 and 804. In the second embodiment of the pixel 21, the capacitive elements 803 and 804 are formed in the second-layer pixel substrate 402, and light incidence on the capacitive elements 803 and 804 is suppressed by the light shielding film 481. Therefore, in both the first and second embodiments, the parasitic light reception sensitivity is suppressed.

### 8. Configuration Example of Three Layer Substrate

In the first and second embodiments described above, the solid-state imaging device 1 is configured by stacking two substrates of the first-layer pixel substrate 51 or 401 as the first substrate and the second-layer pixel substrate 52 or 402 as the second substrate.

However, the solid-state imaging device 1 can also be configured by laminating three substrates.

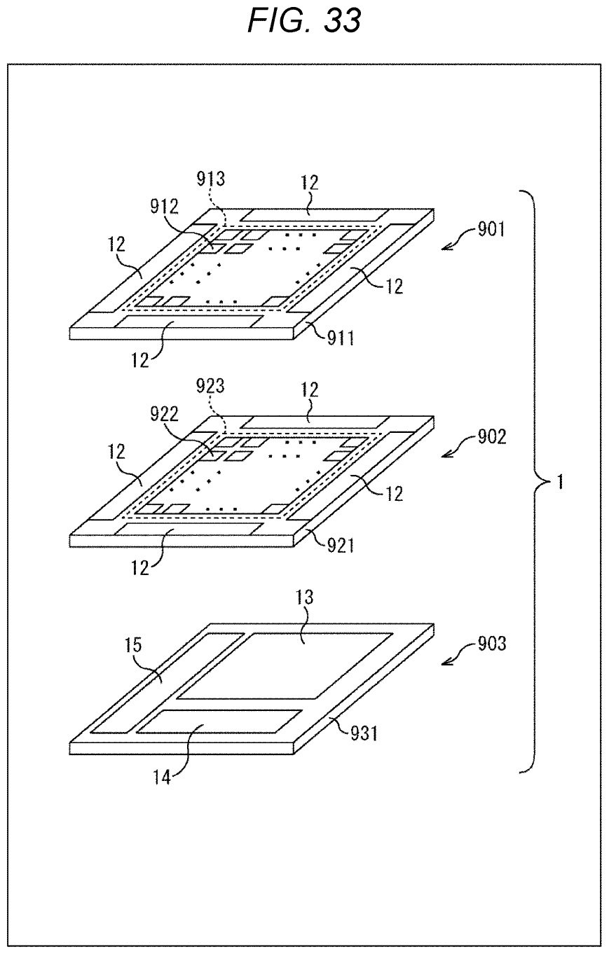

FIG. 33 illustrates a schematic configuration example of the solid-state imaging device 1 in a case where three substrates are stacked.

The solid-state imaging device 1 is configured by laminating three substrates of a first substrate 901, a second substrate 902, and a third substrate 903.

In the first substrate 901, a pixel region 913 including a plurality of sensor pixels 912 is formed in a central portion, and a vertical drive unit 12 is formed around the pixel region 913. The sensor pixel 912 corresponds to, for example, a circuit formed on the first-layer pixel substrate among the pixel circuits illustrated in FIG. 32.

In the second substrate 902, a reading circuit region 923 including a plurality of reading circuits 922 is formed in a central portion, and a vertical drive unit 12 is formed around the reading circuit region 923. The readout circuit 922 corresponds to, for example, a circuit formed on the second-layer pixel substrate among the pixel circuits illustrated in FIG. 32. Note that the vertical drive unit 12 may be formed only on the first substrate 901 or only on the second substrate 902.

On the third substrate 903, a column processing unit 13, a horizontal driving unit 14, and a system control unit 15 are formed. The first substrate 901 and the second substrate 902, and the second substrate 902 and the third substrate 903 are electrically connected by, for example, a through via or a Cu-Cu metal bond.

By stacking three substrates as described above, the solid-state imaging device 1 can be formed with a chip size equivalent to that of the past even in a case where the number of pixels or a pixel circuit is increased. Alternatively, in the case of the same number of pixels or pixel circuits as before, it is possible to provide the solid-state imaging device 1 in which the chip size is further reduced.

### 9. Usage Example of Image Sensor

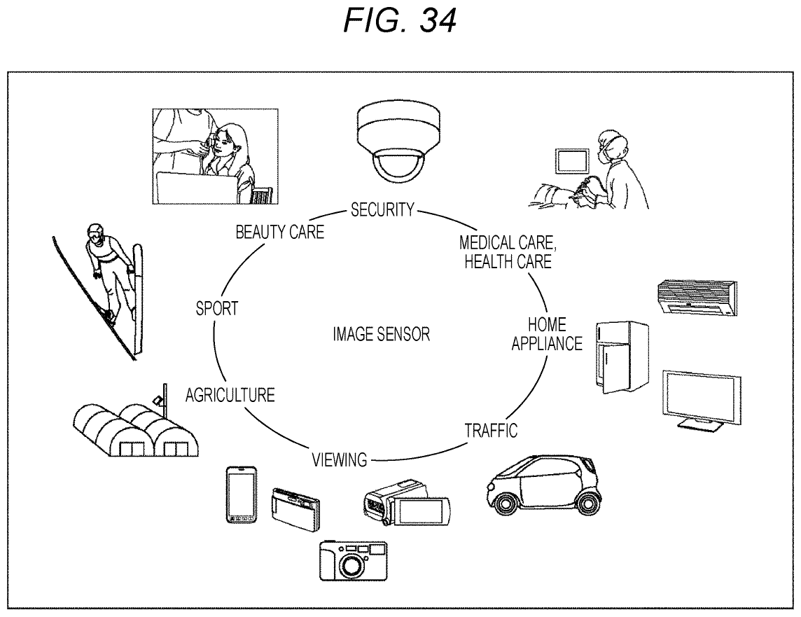

FIG. 34 is a diagram illustrating a usage example of an image sensor using the above-described solid-state imaging device 1.

The above-described solid-state imaging device 1 can be used as an image sensor in various cases of sensing light such as visible light, infrared light, ultraviolet light, and X-rays as described below, for example.
A device that captures an image to be used for viewing, such as a digital camera and a portable device with a camera function.
A device for traffic purpose such as an in-vehicle sensor which takes images of the front, rear, surroundings, interior and the like of an automobile, a surveillance camera for monitoring traveling vehicles and roads, and a ranging sensor which measures a distance between vehicles and the like for safe driving such as automatic stop, recognition of a driver's condition and the like.
A device for home appliance such as a television, a refrigerator, and an air conditioner that images a user's gesture and performs device operation according to the gesture
A device for medical and health care use such as an endoscope and a device that performs angiography by receiving infrared light
A device for security use such as a security monitoring camera and an individual authentication camera
A device used for beauty care, such as a skin measuring instrument for imaging skin, and a microscope for imaging the scalp
A device used for sport, such as an action camera or a wearable camera for sports applications or the like
A device used for agriculture, such as a camera for monitoring a condition of a field or crop.

### 10. Application Example to Electronic Device

Application of the technology of the present disclosure is not limited to that to the solid-state imaging device. That is to say, the technology of the present disclosure may be generally applied to electronic devices in which the solid-state imaging device is used in an image capturing unit (photoelectric converting unit) such as an imaging device such as a digital still camera and a video camera, a portable terminal device having an imaging function, and a copying machine in which the solid-state imaging device is used in the image reading unit. The solid-state imaging device may be formed as one chip, or may be in a module form having an imaging function in which an imaging unit and a signal processing unit or an optical system are packaged together.

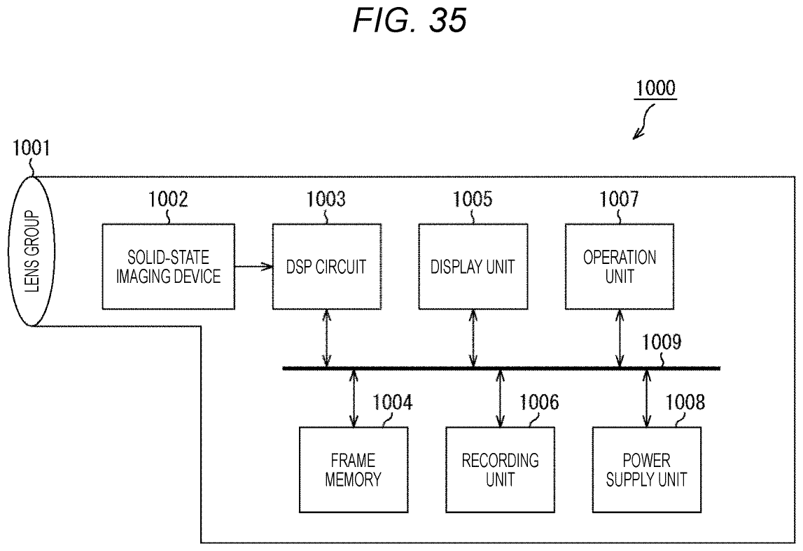

FIG. 35 is a block diagram illustrating a configuration example of an imaging device as an electronic apparatus to which the technology of the present disclosure is applied.

An imaging device 1000 in FIG. 35 includes an optical unit 1001 including a lens group and the like, a solid-state imaging device (imaging device) 1002 in which the configuration of the solid-state imaging device 1 in FIG. 1 is adopted, and a digital signal processor (DSP) circuit 1003 that is a camera signal processing circuit. Furthermore, the imaging device 1000 also includes a frame memory 1004, a display unit 1005, a recording unit 1006, an operation unit 1007, and a power supply unit 1008. The DSP circuit 1003, the frame memory 1004, the display unit 1005, the recording unit 1006, the operation unit 1007, and the power supply unit 1008 are connected to one another via a bus line 1009.

The optical unit 1001 captures incident light (image light) from a subject and forms an image on an imaging surface of the solid-state imaging device 1002. The solid-state imaging device 1002 converts the light amount of the incident light imaged on the imaging surface by the optical unit 1001 into an electrical signal for each pixel and outputs the electrical signal as a pixel signal. As the solid-state imaging device 1002, the solid-state imaging device 1 including the pixel 21 according to the first embodiment or the second embodiment described above, that is, the solid-state imaging device including the pixel 21 in which parasitic light reception sensitivity is suppressed by including the dielectric multilayer film 73 or the light shielding film 481 can be used.

The display unit 1005 includes, for example, a thin display such as a liquid crystal display (LCD) or an organic electro luminescence (EL) display, and displays a moving image or a still image captured by the solid-state imaging device 1002. The recording unit 1006 records the moving image or the still image captured by the solid-state imaging device 1002 on a recording medium such as a hard disk or a semiconductor memory.

The operation unit 1007 issues an operation command regarding various functions of the imaging device 1000 under operation by a user. The power supply unit 1008 appropriately supplies various kinds of power that is the operating power supply for the DSP circuit 1003, the frame memory 1004, the display unit 1005, the recording unit 1006, and the operation unit 1007, to these supply targets.

As described above, the parasitic light reception sensitivity can be suppressed by using the solid-state imaging device 1 to which the first embodiment or the second embodiment is applied as the solid-state imaging device 1002. Therefore, even in the imaging device 100 such as a video camera, a digital still camera, and a camera module for a mobile device such as a mobile phone, noise such as surge, heat, and electromagnetism can be blocked, and high image quality of a captured image can be achieved.

### 11. Application to General Photodetection Device

In the above-described example, an example in which the technology of the present disclosure is applied to a solid-state imaging device that outputs an image signal has been described. However, the technology of the present disclosure can be applied not only to a solid-state imaging device but also to all photodetection devices including pixels that receive and photoelectrically convert incident light. For example, the present invention can also be applied to a light receiving device (distance measuring sensor) of a distance measuring system that receives infrared light emitted as active light and measures a distance to a subject by a direct ToF method or an indirect ToF method. Furthermore, the present disclosure can be applied not only to a CMOS solid-state imaging device but also to a charge coupled device (CCD) solid-state imaging device.

### 12. Application Example to Mobile Body

The technology according to the present disclosure (present technology) can be applied to various products. For example, the technology according to the present disclosure may be achieved in a form of an apparatus to be mounted to a mobile body of any kind such as an automobile, an electric vehicle, a hybrid electric vehicle, a motorcycle, a bicycle, a personal mobility, an airplane, a drone, a vessel, a robot, and the like.

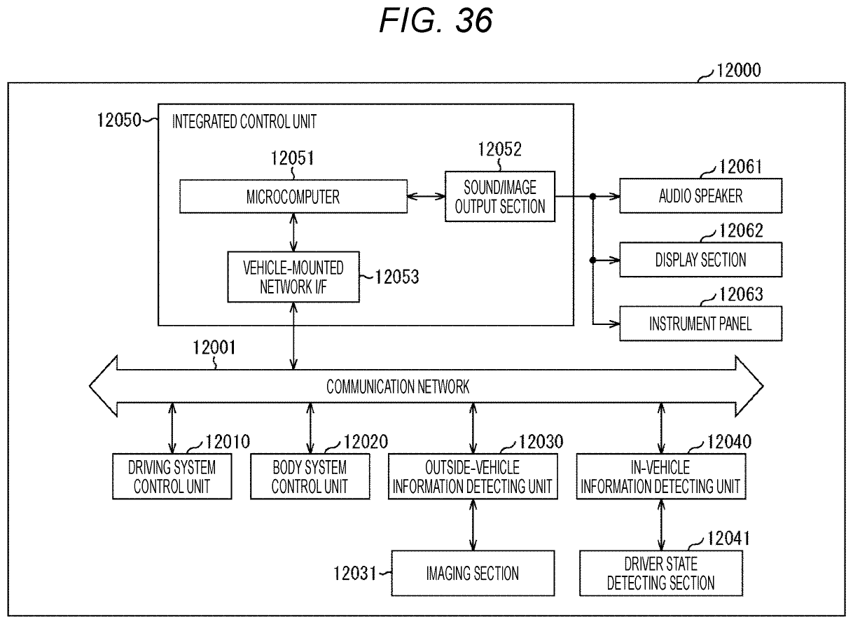

FIG. 36 is a block diagram illustrating a schematic configuration example of a vehicle control system as an example of a mobile body control system to which the technology of the present disclosure is applied.

The vehicle control system 12000 includes a plurality of electronic control units connected to each other via a communication network 12001. In the example illustrated in FIG. 36, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 36, an audio speaker 12061, a display section 12062, and an instrument panel 12063 are exemplified as the output device. The display section 12062 may, for example, include at least one of an on-board display and a head-up display.

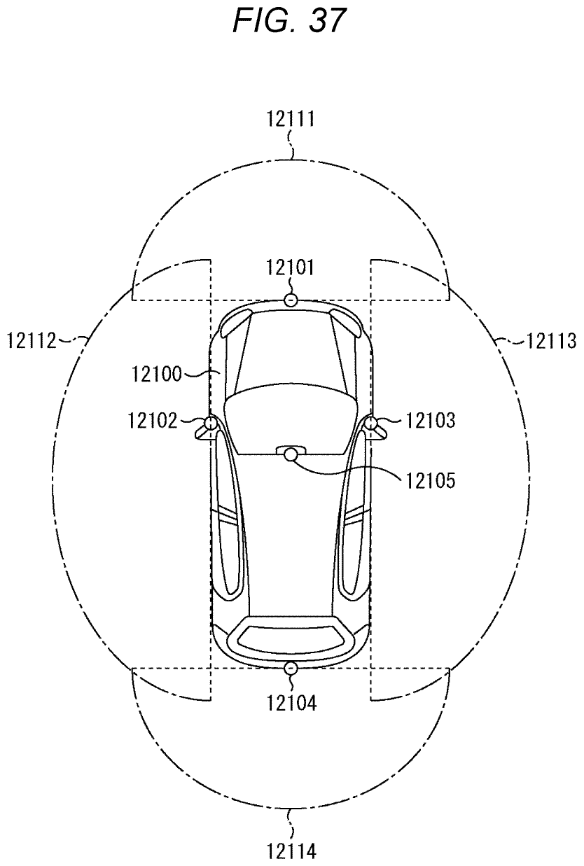

FIG. 37 is a diagram illustrating an example of an installation position of the imaging section 12031.

In FIG. 37, a vehicle 12100 includes imaging sections 12101, 12102, 12103, 12104, and 12105, as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle, and the like. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Note that FIG. 37 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology of the present disclosure can be applied to the imaging section 12031 among the configurations described above. Specifically, the solid-state imaging device 1 including the pixels 21 according to the first embodiment or the second embodiment described above can be applied as the imaging section 12031. By applying the technology according to the present disclosure to the imaging section 12031, it is possible to obtain a more easily-viewed taken image and obtain distance information while reducing the size. Furthermore, it is possible to reduce driver's fatigue and increase the safety of the driver and the vehicle by using the obtained captured image and distance information.

In the above-described example, the solid-state imaging device in which the first conductivity type is the P-type, the second conductivity type is the N-type, and electrons are used as signal charges has been described, but the present disclosure can also be applied to a solid-state imaging device in which holes are used as signal charges. That is, the first conductivity type may be the N-type, the second conductivity type may be the P-type, and the conductivity types of the above-described respective semiconductor regions may be reversed.

Furthermore, the present disclosure is not limited to application to a solid-state imaging device that detects distribution of the amount of incident light of visible light and captures the distribution as an image, and can be applied to all solid-state imaging devices (physical quantity distribution detection devices) such as a solid-state imaging device that captures distribution of the amount of incident infrared rays, X-rays, particles, or the like as an image, and a fingerprint detection sensor that detects distribution of other physical quantities such as pressure and capacitance and captures the distribution as an image in a broad sense.

Furthermore, the technology of the present disclosure is applicable not only to a solid-state imaging device but also to all semiconductor devices having other semiconductor integrated circuits.

The embodiment of the present disclosure is not limited to the above-described embodiments and various modifications may be made without departing from the gist of the technology of the present disclosure.

For example, it is possible to adopt a mode obtained by combining all or some of the plurality of embodiments described above.

Note that, the effects described in the present specification are merely examples and are not limited, and there may be effects other than those described in the present specification.

Note that the technology of the present disclosure can have the following configurations.

(1)

A photodetection device including:
a first substrate including a first semiconductor substrate on which at least a photoelectric conversion unit is formed;
a second substrate including a second semiconductor substrate on which an active element is formed; and
a dielectric multilayer film configured by alternately stacking at least three or more layers of a first film using a dielectric material having a first refractive index and a second film using a dielectric material having a second refractive index lower than the first refractive index, the dielectric multilayer film being disposed between the first semiconductor substrate and the second semiconductor substrate.

(2)

The photodetection device according to (1) described above, in which
the first substrate further includes a first wiring layer, and
the dielectric multilayer film is disposed between the first wiring layer and the first semiconductor substrate.

(3)

The photodetection device according to (1) described above, in which
the first substrate includes an insulating film between the first semiconductor substrate and the dielectric multilayer film, and is configured not to include a wiring layer between the first semiconductor substrate and the dielectric multilayer film.

(4)

The photodetection device according to (1) described above, in which
the first substrate further includes a first wiring layer and a second wiring layer, and
the dielectric multilayer film is disposed between the first wiring layer and the second wiring layer.

(5)

The photodetection device according to (1) described above, in which
the dielectric multilayer film includes at least two layers of a first dielectric multilayer film and a second dielectric multilayer film.

(6)

The photodetection device according to (1) described above, in which
the first substrate further includes a first wiring layer and a second wiring layer,
the first dielectric multilayer film is disposed between the first semiconductor substrate and the first wiring layer, and
the second dielectric multilayer film is disposed between the first wiring layer and the second wiring layer.

(7)

The photodetection device according to any one of (1) to (6) described above, in which
the second substrate includes, for each pixel, two capacitive elements that hold two signals to be subjected to AD conversion.

(8)

The photodetection device according to (1) described above, in which
the dielectric multilayer film is formed only in a part of a light receiving region of each pixel in a planar direction.

(9)

The photodetection device according to (1) described above, in which
the dielectric multilayer film includes two regions of different numbers of stacked layers in a planar direction.

(10)

The photodetection device according to any one of (1) to (9) described above, in which
the dielectric materials of the first film and the second film are insulating materials.

(11)

The photodetection device according to (1) described above, further including
a through electrode penetrating the dielectric multilayer film,
in which the through electrode is configured to be in contact with the dielectric multilayer film.

(12)

The photodetection device according to (1) described above, further including
a wiring at a predetermined depth position in the dielectric multilayer film,
in which the wiring is configured to be in contact with the dielectric multilayer film.

(13)

The photodetection device according to any one of (1) to (12) described above, in which
the dielectric materials of the first film and the second film include any of a silicon compound, polysilicon, amorphous silicon, and a metal compound containing an oxide or a nitride.

(14)

A photodetection device including:
a first substrate including a first semiconductor substrate on which at least a photoelectric conversion unit is formed; and
a second substrate including a second semiconductor substrate on which an active element is formed,
in which the first substrate and the second substrate are stacked, and
the second substrate includes a light shielding film on the second semiconductor substrate.

(15)

The photodetection device according to (14) described above, in which
the light shielding film is disposed in the second semiconductor substrate.

(16)

The photodetection device according to (14) described above, in which
the light shielding film is disposed at the bottom of the second semiconductor substrate so as to be in contact with an interlayer insulating film of the first substrate.

(17)

The photodetection device according to any one of (14) to (16) described above, in which
the light shielding film is configured by embedding a metal material in a lateral trench formed by crystal anisotropic etching.

(18)

The photodetection device according to (17) described above, in which
the lateral trench is formed by the crystal anisotropic etching from a vertical trench formed in the second semiconductor substrate after the active element is formed by bonding the first substrate and the second substrate together.

(19)

The photodetection device according to any one of (14) to (18) described above, in which
the second substrate includes an amplification transistor as the active element, and
the amplification transistor has a gate electrode structure having a dug structure.

(20)

The photodetection device according to any one of (14) to (19) described above, in which
the second substrate includes, for each pixel, two capacitive elements that hold two signals to be subjected to AD conversion.

### REFERENCE SIGNS LIST

1 Solid-state imaging device
11 Pixel array unit
21 Pixel
72 Wiring layer
72A First wiring layer
72B Second wiring layer
73 Dielectric multilayer film
73A First dielectric multilayer film
73B Second dielectric multilayer film
81 Semiconductor substrate
82 Wiring layer
83 Insulating film
91 (91A, 91B) Wiring
92 (92A, 92B) Interlayer insulating film
100 Imaging device
101 First film (high refractive index film)
102 Second film (low refractive index film)
103, 103A Through electrode
104, 104A Through electrode
105 Insulating film
106 Insulating film
111 Wiring
112 Interlayer insulating film
151, 152, 161, 171, 181 Through hole
201 Wiring
202 Wiring
211 Contact wiring
212 Contact wiring
231 Included portion
241 Insulating film
251, 271 Through electrode
281 Wiring
301 Diffusion layer
321 to 323 Through electrode
341 Insulating film
421 Semiconductor substrate
422 Wiring layer
431 Semiconductor substrate
432 Wiring layer
442 N-type semiconductor region
443 Pixel separation portion
444 N-type diffusion layer
445 P-type diffusion layer
446 Vertical gate electrode
447 Contact electrode
451 Interlayer insulating film
481 Light shielding film
482 Insulating film
482A Oxide film
482B Oxide film
483 Vertical trench
484 Embedded metal portion
485 Insulating film
485A Oxide film
485B Oxide film
486 N-type diffusion layer
491 Wiring
491A, 491A′ Wiring
492 Interlayer insulating film
493 Contact wiring
501 Through via
502 Contact wiring
551 Insulating film
552 Wiring
561 Through hole
571 Silicon nitride film
572 Silicon-oxide film
574 Vertical trench
575 Sidewall
581 Lateral trench
582 Polysilicon
592 Through hole
593 Through hole
601 Through via
661 Trench
662 Trench
671 Vertical trench
672 Sidewall
681 Lateral trench
682 Polysilicon
692 Through hole
702 Through hole
712 Through hole
751 Gate electrode
751A Planar gate section
751B Dug portion
1000 Imaging device
1002 Solid-state imaging device

1. A photodetection device comprising:
a first substrate including a first semiconductor substrate on which at least a photoelectric conversion unit is formed;
a second substrate including a second semiconductor substrate on which an active element is formed; and
a dielectric multilayer film configured by alternately stacking at least three or more layers of a first film using a dielectric material having a first refractive index and a second film using a dielectric material having a second refractive index lower than the first refractive index, the dielectric multilayer film being disposed between the first semiconductor substrate and the second semiconductor substrate.

2. The photodetection device according to claim 1, wherein
the first substrate further includes a first wiring layer, and
the dielectric multilayer film is disposed between the first wiring layer and the first semiconductor substrate.

3. The photodetection device according to claim 1, wherein
the first substrate includes an insulating film between the first semiconductor substrate and the dielectric multilayer film, and is configured not to include a wiring layer between the first semiconductor substrate and the dielectric multilayer film.

4. The photodetection device according to claim 1, wherein
the first substrate further includes a first wiring layer and a second wiring layer, and
the dielectric multilayer film is disposed between the first wiring layer and the second wiring layer.

5. The photodetection device according to claim 1, wherein
the dielectric multilayer film includes at least two layers of a first dielectric multilayer film and a second dielectric multilayer film.

6. The photodetection device according to claim 5, wherein
the first substrate further includes a first wiring layer and a second wiring layer,
the first dielectric multilayer film is disposed between the first semiconductor substrate and the first wiring layer, and
the second dielectric multilayer film is disposed between the first wiring layer and the second wiring layer.

7. The photodetection device according to claim 1, wherein
the second substrate includes, for each pixel, two capacitive elements that hold two signals to be subjected to AD conversion.

8. The photodetection device according to claim 1, wherein
the dielectric multilayer film is formed only in a part of a light receiving region of each pixel in a planar direction.

9. The photodetection device according to claim 1, wherein
the dielectric multilayer film includes two regions of different numbers of stacked layers in a planar direction.

10. The photodetection device according to claim 1, wherein
the dielectric materials of the first film and the second film are insulating materials.

11. The photodetection device according to claim 1, further comprising
a through electrode penetrating the dielectric multilayer film,
wherein the through electrode is configured to be in contact with the dielectric multilayer film.

12. The photodetection device according to claim 1, further comprising
a wiring at a predetermined depth position in the dielectric multilayer film,
wherein the wiring is configured to be in contact with the dielectric multilayer film.

13. The photodetection device according to claim 1, wherein
the dielectric materials of the first film and the second film include any of a silicon compound, polysilicon, amorphous silicon, and a metal compound containing an oxide or a nitride.

14. A photodetection device comprising:
a first substrate including a first semiconductor substrate on which at least a photoelectric conversion unit is formed; and
a second substrate including a second semiconductor substrate on which an active element is formed,
wherein the first substrate and the second substrate are stacked, and
the second substrate includes a light shielding film on the second semiconductor substrate.

15. The photodetection device according to claim 14, wherein
the light shielding film is disposed in the second semiconductor substrate.

16. The photodetection device according to claim 14, wherein
the light shielding film is disposed at the bottom of the second semiconductor substrate so as to be in contact with an interlayer insulating film of the first substrate.

17. The photodetection device according to claim 14, wherein
the light shielding film is configured by embedding a metal material in a lateral trench formed by crystal anisotropic etching.

18. The photodetection device according to claim 17, wherein
the lateral trench is formed by the crystal anisotropic etching from a vertical trench formed in the second semiconductor substrate after the active element is formed by bonding the first substrate and the second substrate together.

19. The photodetection device according to claim 14, wherein
the second substrate includes an amplification transistor as the active element, and
the amplification transistor has a gate electrode structure having a dug structure.

20. The photodetection device according to claim 14, wherein
the second substrate includes, for each pixel, two capacitive elements that hold two signals to be subjected to AD conversion.
